(19) United States
(12) Patent Application Publication
(10) Pub. No.: US 2026/0101659 A1
(43) Pub. Date: Apr. 9, 2026

(54) DISPLAY PANEL AND DISPLAY DEVICE

(71) Applicant: Xiamen Tianma Display Technology Co., Ltd., Xiamen (CN)

(72) Inventors: Xuehuan FENG, Xiamen (CN); Lizi LIN, Xiamen (CN); Yana GAO, Xiamen (CN); Xingyao ZHOU, Xiamen (CN); Zhiqiang XIA, Xiamen (CN); Kang YANG, Xiamen (CN)

(73) Assignee: Xiamen Tianma Display Technology Co., Ltd., Xiamen (CN)

(21) Appl. No.: 19/405,825

(22) Filed: Dec. 2, 2025

(30) Foreign Application Priority Data
Jun. 27, 2025 (CN) 202510884496.1

(51) Int. Cl. H10K 59/80; H10K 59/123

(52) U.S. Cl. CPC H10K 59/80515; H10K 59/123

(57) ABSTRACT

A display panel includes a substrate; multiple pixel circuits and multiple light-emitting elements located on one side of the substrate; and multiple anode connection portions. A light-emitting element includes an anode. At least part of the anode connection portions each include a connection subportion and a compensation subportion. The connection subportion connects a pixel circuit and the anode. The anode connection portions and anodes of the light-emitting elements are disposed in different layers. The compensation subportion is located on the side of the anode facing the substrate. Along the thickness direction of the display panel, at least part of the compensation subportion does not overlap the connection subportion.

### CROSS-REFERENCE TO RELATED APPLICATION

This application claims priority to Chinese Patent Application No.202510884496.1 filed Jun. 27, 2025, the disclosure of which is incorporated herein by reference in its entirety.

### TECHNICAL FIELD

Embodiments of the present invention relate to the field of display technology, particularly a display panel and a display device.

### BACKGROUND

With the continuous development of display technology, display panels have been widely applied in production and life. A light-emitting element of a display panel includes an anode electrode and a cathode electrode. The anode electrode is connected to a pixel circuit to enable the pixel circuit to drive the light-emitting element to emit light for display, thereby ensuring the display effect of the display panel.

To better meet user requirements, fine adjustments may be made to certain film layer structures in a display panel, thereby enhancing the overall display effect of the display panel.

### SUMMARY

Embodiments of the present invention provide a display panel and a display device, in which the compensation subportion is disposed at the anode connection portion, thereby increasing the overall area of the anode connection portion, improving the overall flatness of the display panel, and ensuring the display effect of the display panel.

In a first aspect, embodiments of the present invention provide a display panel. The display panel includes a substrate; multiple pixel circuits and multiple light-emitting elements located on one side of the substrate; and multiple anode connection portions. A light-emitting element includes an anode. At least part of the anode connection portions each include a connection subportion and a compensation subportion.

The connection subportion connects a pixel circuit and the anode. The anode connection portions and anodes of the light-emitting elements are disposed in different layers.

The compensation subportion is located on the side of the anode facing the substrate. Along the thickness direction of the display panel, at least part of the compensation subportion does not overlap the connection subportion.

In a second aspect, based on the same inventive concept, embodiments of the present invention provide a display device. The display device includes the display panel of the first aspect.

It is to be understood that the content described in this section is neither intended to identify key or critical features of the embodiments of the present invention nor intended to limit the scope of the present invention. Other features of the present invention become easily understood through the description provided below.

### BRIEF DESCRIPTION OF DRAWINGS

To illustrate technical solutions in example embodiments of the present invention more clearly, the drawings used in the description of the embodiments are briefly described below. Apparently, the described drawings are only part, not all, of drawings of the embodiments of the present invention to be described, and those of ordinary skill in the art may obtain other drawings based on the drawings described below on the premise that no creative work is done.

FIG. 1 is a diagram illustrating the structure of a display panel according to embodiments of the present invention.

FIG. 2 is a circuit diagram of a pixel circuit according to embodiments of the present invention.

FIG. 3 is a timing diagram of an implementation of signals provided for the pixel circuit of FIG. 2 in one drive cycle according to embodiments of the present invention.

FIG. 4 is a diagram illustrating the structure of film layers of the pixel circuit of FIG. 2.

FIG. 5 is a section view of a pixel circuit according to embodiments of the present invention.

FIG. 6 is a diagram illustrating the structure of stacked film layers of a display panel according to embodiments of the present invention.

FIG. 7 is a diagram illustrating part of the structure of the stacked film layers of FIG. 6.

FIG. 8 is a diagram illustrating part of the structure of the stacked film layers of FIG. 6.

FIG. 9 is a diagram illustrating the structure of the first part of film layers of FIG. 6.

FIG. 10 is a diagram illustrating the structure of the second part of film layers of FIG. 6.

FIG. 11 is a diagram illustrating the structure of the third part of film layers of FIG. 6.

FIG. 12 is a diagram illustrating the structure of the fourth part of film layers of FIG. 6.

FIG. 13 is a diagram illustrating the structure of the fifth part of film layers of FIG. 6.

FIG. 14 is a first diagram illustrating the structure of the sixth part of film layers of FIG. 6.

FIG. 15 is a diagram illustrating the structure of the seventh part of film layers of FIG. 6.

FIG. 16 is a diagram illustrating the structure of stacked film layers of a display panel according to embodiments of the present invention.

FIG. 17 is a diagram illustrating part of the structure of the stacked film layers of FIG. 16.

FIG. 18 is a diagram illustrating the structure of the first part of film layers of FIG. 16.

FIG. 19 is a diagram illustrating the structure of the second part of film layers of FIG. 16.

FIG. 20 is a diagram illustrating the structure of the third part of film layers of FIG. 16.

FIG. 21 is a diagram illustrating the structure of the fourth part of film layers of FIG. 16.

FIG. 22 is a diagram illustrating the structure of the fifth part of film layers of FIG. 16.

FIG. 23 is a first diagram illustrating the structure of the sixth part of film layers of FIG. 16.

FIG. 24 is a diagram illustrating the structure of the seventh part of film layers of FIG. 16.

FIG. 25 is a second diagram illustrating the structure of the sixth part of film layers of FIG. 6.

FIG. 26 is a second diagram illustrating the structure of the sixth part of film layers of FIG. 16.

FIG. 27 is a third diagram illustrating the structure of the sixth part of film layers of FIG. 6.

FIG. 28 is a third diagram illustrating the structure of the sixth part of film layers of FIG. 16.

FIG. 29 is an enlarged view of an anode connection portion according to embodiments of the present invention.

FIG. 30 is a first section view taken along line F-F′ of FIG. 29.

FIG. 31 is a first section view taken along line F-F′ of FIG. 29.

FIG. 32 is a first section view taken along line F-F′ of FIG. 29.

FIG. 33 is a third diagram illustrating the structure of the sixth part of film layers of FIG. 16.

FIG. 34 is a fourth diagram illustrating the structure of the sixth part of film layers of FIG. 16.

FIG. 35 is a first section view taken along line P-P′ of FIG. 1.

FIG. 36 is a second section view taken along line P-P′ of FIG. 1.

FIG. 37 is a diagram illustrating the orthographic projections of a light-transmissive hole and signal lines on a substrate according to embodiments of the present invention.

FIG. 38 is a diagram illustrating the orthographic projections of a light-transmissive hole and signal lines on a substrate according to embodiments of the present invention.

FIG. 39 is a diagram illustrating the structure of a display device according to embodiments of the present invention.

### DETAILED DESCRIPTION

The present invention is further described in detail below in conjunction with the drawings and embodiments. It is to be understood that the embodiments described herein are intended to illustrate the present invention and not to limit the present invention. Additionally, it is to be noted that for ease of description, only part, not all, of structures related to the present invention are illustrated in the drawings.

It is to be noted that terms such as “first” and “second” in the description, claims, and drawings of the present invention are used for distinguishing between similar objects and are not necessarily used for describing a particular order or sequence. It is to be understood that data used in this manner are interchangeable where appropriate so that the embodiments of the present invention described herein can be implemented in order not illustrated or described herein. Additionally, terms “including”, “having”, and any variations thereof are intended to encompass a non-exclusive inclusion. For example, a system, product, or device that includes a series of units not only includes the expressly listed steps or units but may also include other units that are not expressly listed or are inherent to the product or device.

It is apparent to those skilled in the art that various modifications and variations can be made to the present invention without departing from the spirit or scope of the present invention. Therefore, the present invention is intended to cover modifications and variations of the present invention that fall within the scope of the corresponding claims (the claimed technical solutions) and equivalents thereof. It is to be noted that if not in collision, embodiments of the present invention may be combined with each other.

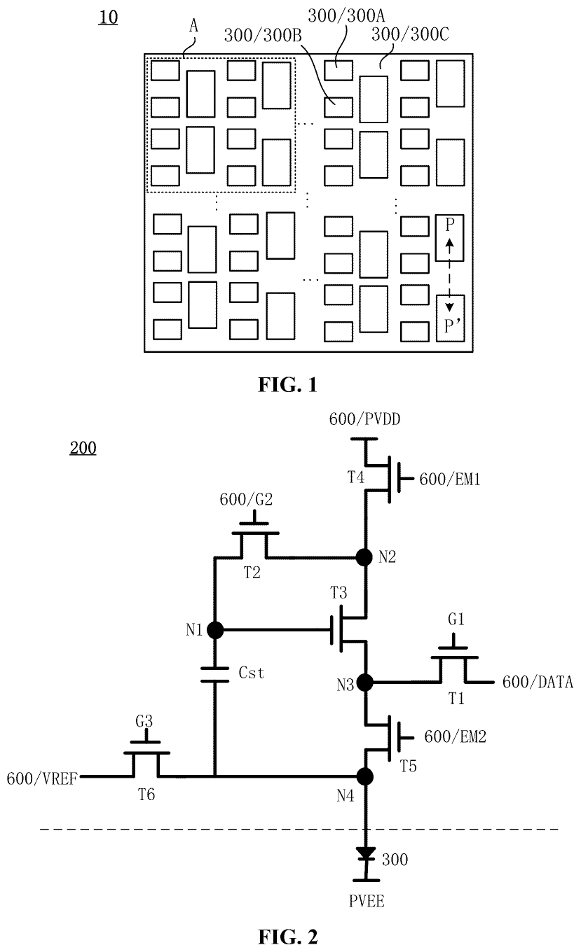

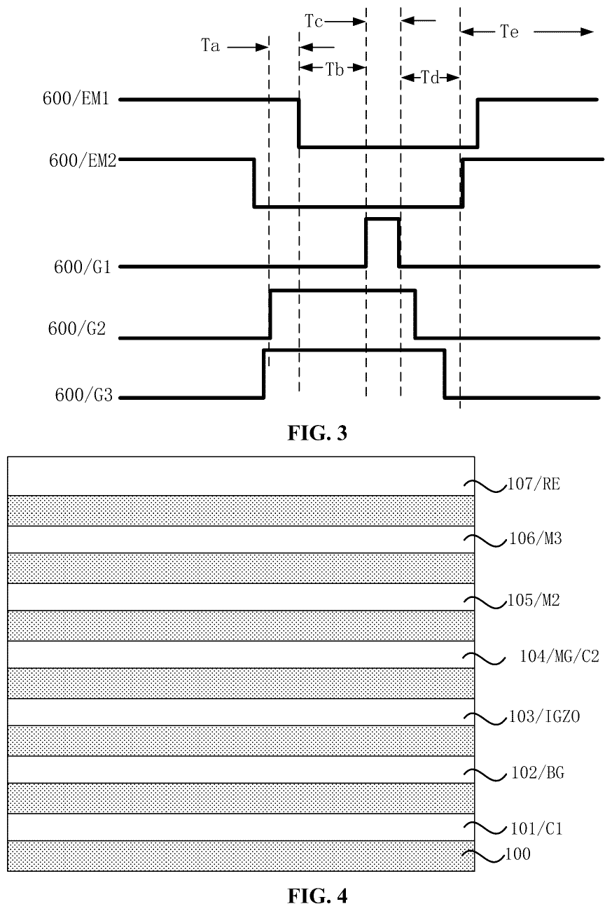

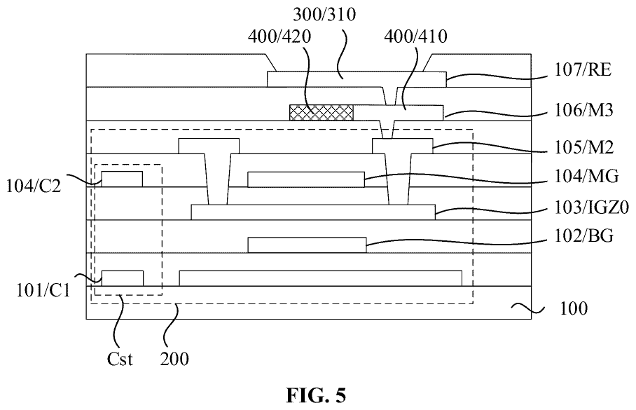

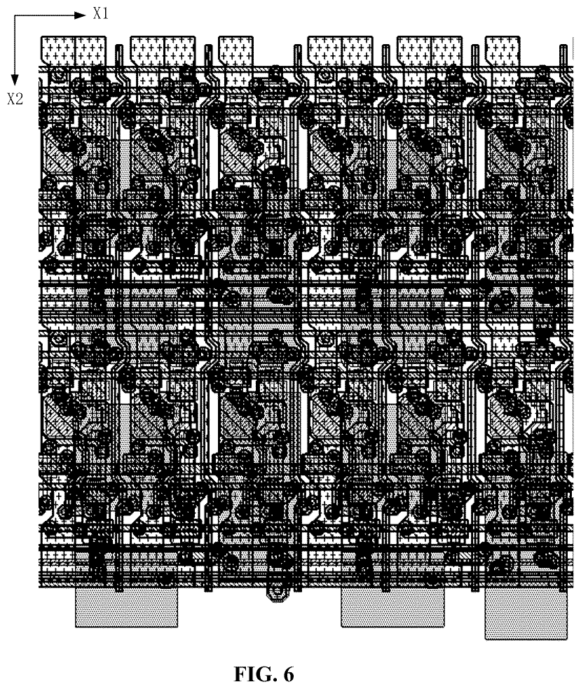

FIG. 1 is a diagram illustrating the structure of a display panel according to embodiments of the present invention. FIG. 2 is a circuit diagram of a pixel circuit according to embodiments of the present invention. FIG. 3 is a timing diagram of an implementation of signals provided for the pixel circuit of FIG. 2 in one drive cycle according to embodiments of the present invention. FIG. 4 is a diagram illustrating the structure of film layers of the pixel circuit of FIG. 2. FIG. 5 is a section view of a pixel circuit according to embodiments of the present invention. Referring to FIG. 1 to FIG. 5, embodiments of the present invention provide a display panel 10. The display panel 10 includes a substrate 100; multiple pixel circuits 200 and multiple light-emitting elements 300 located on one side of the substrate 100; and multiple anode connection portions 400. A light-emitting element 300 includes an anode 310. At least part of the anode connection portions 400 each include a connection subportion 410 and a compensation subportion 420. The connection subportion 410 connects a pixel circuit 200 and the anode 310. The anode connection portions 400 and anodes 310 of the light-emitting elements 300 are disposed in different layers. The compensation subportion 420 is located on the side of the anode 310 facing the substrate 100. Along the thickness direction of the display panel 10, at least part of the compensation subportion 420 does not overlap the connection subportion 410.

Referring to FIG. 1, the display panel 10 includes multiple light-emitting elements 300. Light emission of the light-emitting elements 300 enables the display function of the display panel 10. The display panel 10 may also include light-emitting elements 300 of different colors, thereby achieving the color display effect of the display panel 10. Further, referring to FIG. 1 and FIG. 2, the display panel 10 also includes pixel circuits 200. The pixel circuit 200 is electrically connected to the light-emitting element 300. The pixel circuit 200 is configured to drive the light-emitting element 300 to perform light emission for display, thereby ensuring the display effect of the display panel 10.

The configuration of the pixel circuit 200 may vary. By way of example, referring to FIG. 2, the pixel circuit 200 is illustrated as a “6T1C” structure, where “T” denotes a transistor and “C” denotes a capacitor. Further, referring to FIG. 2, the transistors in the pixel circuit 200 are all indium-gallium-zinc-oxide (IGZO) transistors. The IGZO transistors have advantages such as small leakage current. In other embodiments, the types of the transistors in the pixel circuit may also include a low-temperature polycrystalline silicon (LTPS) transistor. The LTPS transistor has the advantages of high switching speed, high carrier mobility, and low power. Based on the configuration of the pixel circuit 200, those skilled in the art may make adaptive adjustments as required, such as increasing or decreasing the number of transistors or adjusting the types of transistors.

Optionally, referring to FIG. 2, the pixel circuit 200 may include a data write transistor T1, a threshold compensation transistor T2, a drive transistor T3, a first light emission control transistor T4, a second light emission control transistor T5, a reset transistor T6, and a storage capacitor Cst. Specifically, the timing operation of the pixel circuit 200 shown in FIG. 2 is illustrated by way of example with reference to FIG. 3.

The first light emission control signal line (shown as EM1 in the figure) electrically connected to the control terminal of the first light emission control transistor T4 may control the first light emission control transistor T4 to turn on or off. The second scan signal line (shown as G2 in the figure) electrically connected to the control terminal of the threshold compensation transistor T2 may control the threshold compensation transistor T2 to turn on or off. The third scan signal line (shown as G3 in the figure) electrically connected to the control terminal of the reset transistor T6 may control the reset transistor T6 to turn on or off. In the reset phase Ta of the pixel circuit 200, the first light emission control signal line (shown as EM1 in the figure) controls the first light emission control transistor T4 to turn on (at this time, the first light emission control signal line connected to the control terminal of the first light emission control transistor T4 is at an enable level, which is shown as a high level in FIG. 3). The second scan signal line (shown as G2 in the figure) controls the threshold compensation transistor T2 to turn on (at this time, the scan signal line connected to the control terminal of the threshold compensation transistor T2 is at an enable level, which is shown as a high level in FIG. 3). The power signal in the first power signal line PVDD connected to the input terminal of the first light emission control transistor T4 may be written into the gate of the drive transistor T3 through the first light emission control transistor T4 and the threshold compensation transistor T2, and the first node N1 is reset, so the potential of the control terminal of the drive transistor T3 is the power signal input by the first power signal line PVDD, and when the drive transistor T3 is an oxide transistor, the drive transistor T3 is also in an on state. The storage capacitor Cst can ensure that the potential of the first node N1 is stable. Meanwhile, the third scan signal line (shown as G3 in the figure) controls the reset transistor T6 to turn on (at this time, the scan signal line connected to the control terminal of the reset transistor T6 is at an enable level, which is shown as a high level in FIG. 3), and the reset signal in the reset signal line VREF electrically connected to the input terminal of the reset transistor T6 may be transmitted to the fourth node N4 to reset the light-emitting element 300.

Further, in the compensation preparation phase Tb of the pixel circuit 200, the first light emission control signal line (shown as EM1 in the figure) controls the first light emission control transistor T4 to turn off (at this time, the first light emission control signal line connected to the control terminal of the first light emission control transistor T4 is at a non-enable level, which is shown as a low level in FIG. 3), and the power signal in the first power signal line PVDD connected to the input terminal of the first light emission control transistor T4 stops being written into the pixel circuit 200.

Further, the first scan signal line (shown as G1 in the figure) electrically connected to the control terminal of the data write transistor T1 may control the data write transistor T1 to turn on or off. In the threshold compensation phase Tc of the pixel circuit 200, the first scan signal line (shown as G1 in the figure) controls the data write transistor T1 to turn on (at this time, the scan signal line connected to the control terminal of the data write transistor T1 is at an enable level, which is shown as a high level in FIG. 3). Moreover, the drive transistor T3 and the threshold compensation transistor T2 are in an on state, and the data signal line DATA connected to the input terminal of the data write transistor T1 is written into the first node N1 through the data write transistor T1, the drive transistor T3, and the threshold compensation transistor T2 in sequence. Meanwhile, the third scan signal line (shown as G3 in the figure) still controls the reset transistor T6 to turn on to reset the light-emitting element 300.

In the light emission preparation phase Td of the pixel circuit 200, the first scan signal line (shown as G1 in the figure) controls the data write transistor T1 to turn off (at this time, the scan signal line connected to the control terminal of the data write transistor T1 is at a non-enable level, which is shown as a low level in FIG. 3). In the light emission preparation phase Td of the pixel circuit 200, the second scan signal line (shown as G2 in the figure) controls the threshold compensation transistor T2 to turn off (at this time, the scan signal line connected to the control terminal of the threshold compensation transistor T2 is at a non-enable level, which is changed from a high level to a low level in FIG. 3), and the data signal provided by the data signal line DATA stops being written into the pixel circuit 200. Meanwhile, the third scan signal line (shown as G3 in the figure) still controls the reset transistor T6 to turn off (at this time, the scan signal line connected to the control terminal of the reset transistor T6 is at a non-enable level, which is changed from a high level to a low level in FIG. 3) to stop resetting the light-emitting element 300.

Further, the second light emission control signal line (shown as EM2 in the figure) electrically connected to the control terminal of the second light emission control transistor T5 may control the second light emission control transistor T5 to turn on or off. In the light emission phase Te of the pixel circuit 200, the first light emission control signal line (shown as EM1 in the figure) controls the first light emission control transistor T1 to turn on, and the second light emission control signal line (shown as EM2 in the figure) controls the second light emission control transistor T5 to turn on (at this time, the second light emission control signal line connected to the control terminal of the second light emission control transistor T5 is at an enable level, which is shown as a high level in FIG. 3). The first power signal line PVDD and the second power signal line PVEE are connected, that is, the drive current generated by the drive transistor T3 can be transmitted to the light-emitting element 300, thereby driving the light-emitting element 300 to emit light.

The display panel 10 is formed by multiple stacked film layers. Referring to FIG. 4, the display panel 10 includes a first metal layer 101, a second metal layer 102, a semiconductor layer 103, a third metal layer 104, a fourth metal layer 105, a fifth metal layer 106, an anode metal layer 107, and other layers in sequence from one side of the substrate 100 to the light emission side of the display panel 10. An insulating layer is disposed between two adjacent metal film layers to play a role of signal isolation and planarization. Further, the film layer structure in the pixel circuit 200 of FIG. 2 uses the film layers of FIG. 4. As shown in FIG. 4 and FIG. 5, in the pixel circuit 200, the first gate BG of the transistor is located in the layer where the second metal layer 102 is located, the active layer IGZO of the transistor is located in the layer where the semiconductor layer 103 is located, and the second gate MG of the transistor is located in the layer where the third metal layer 104 is located; and in the pixel circuit 200, the first capacitor plate C1 included in the storage capacitor Cst is located in the layer where the first metal layer 101 is located, and the second capacitor plate C2 of the storage capacitor Cst is located in the layer where the third metal layer 104 is located. The pixel circuit 200 is electrically connected to the anode 310 of the light-emitting element 300. The anode 310 of the light-emitting element 300 may be located in the film layer where the anode metal layer 107 is located. The film layer structure of the pixel circuit 200 may be adaptively adjusted according to actual requirements, for example, some film layers are added or removed. Moreover, any one of the preceding film layers may include at least one sublayer. The film layer structure of the pixel circuit 200 is not limited in embodiments of the present invention.

Further, referring to FIG. 5, the display panel 10 also includes an anode connection portion 400. The anode connection portion 400 is located on the side of the anode 310 facing the substrate 100. The anode connection portion 400 is configured to electrically connect the anode 310 of the light-emitting element 300 to the pixel circuit 200 to ensure that the pixel circuit 200 drives the light-emitting element 300, thereby ensuring the display function of the display panel 10. Specifically, the connection subportion 410 included in the anode connection portion 400 is configured to implement the electrical connection between the pixel circuit 200 and the anode 310. Further, referring to FIG. 5, part of the anode connection portions 400 of the display panel 10 each include a compensation subportion 420. Along the thickness direction of the display panel 10, part of the compensation subportion 420 does not overlap the connection subportion 410. Adding the compensation subportion 420 is equivalent to increasing the orthographic projection area of the entire anode connection portion 400 on the substrate. By increasing the overall area of the anode connection portion 400, it is possible to ensure that the subsequently prepared anode 310 can be more stable at this position and improve the overall flatness of the display panel. It is also possible to ensure the same or similar light transmittance across different regions of the display panel 10, ensure a consistent optical effect across different regions of the display panel 10, and ensure the display effect of the display panel 10.

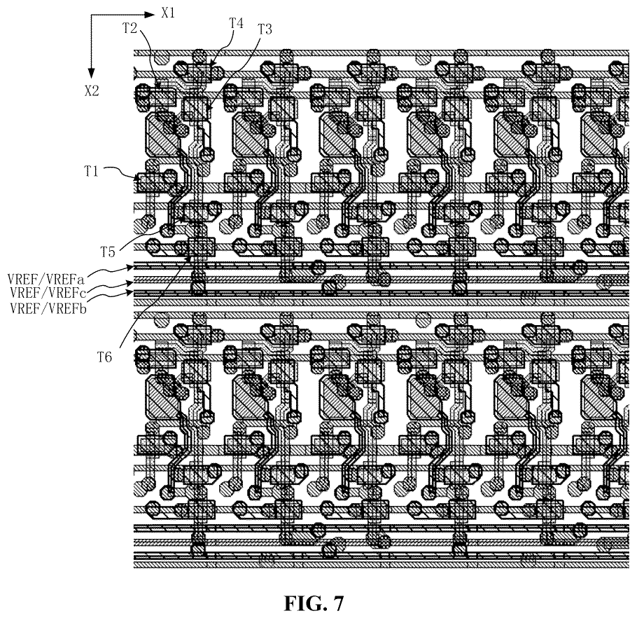

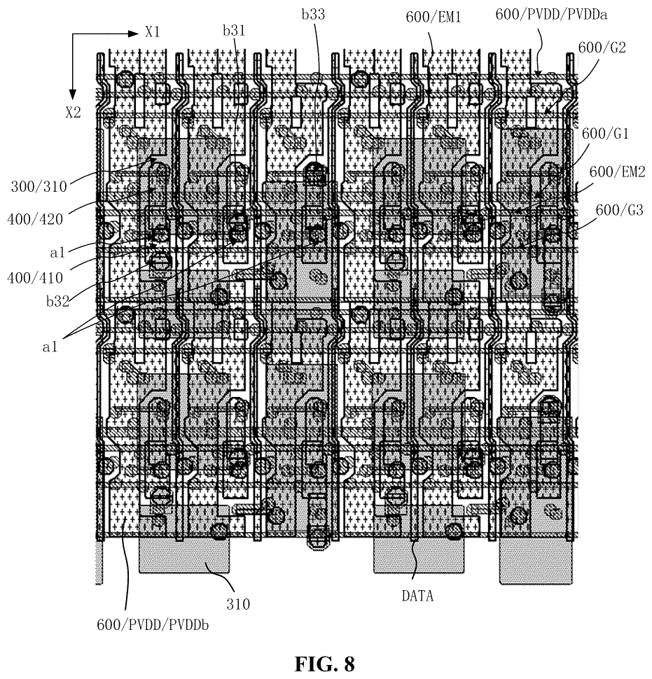

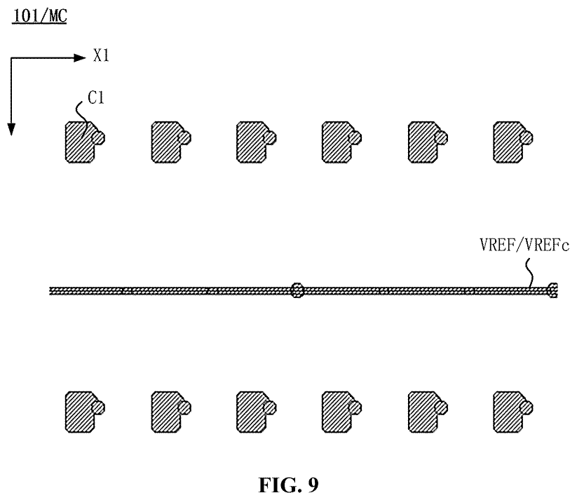

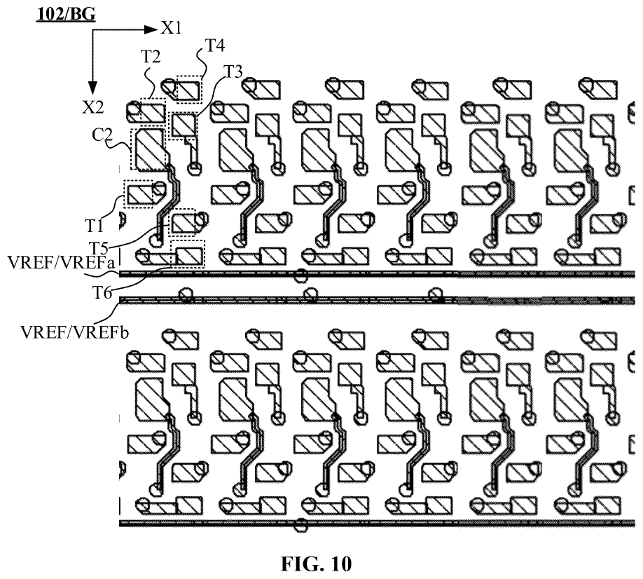

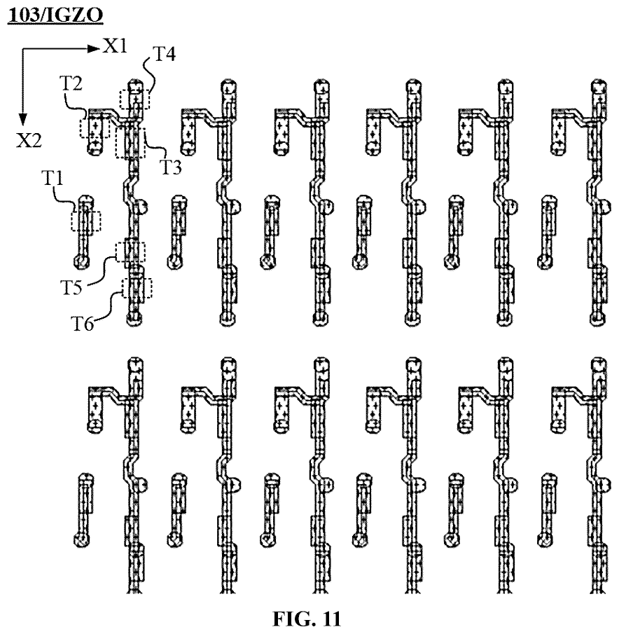

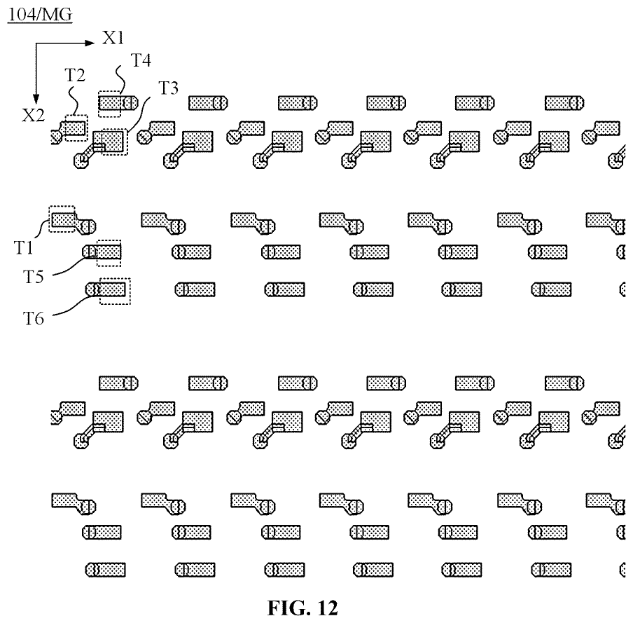

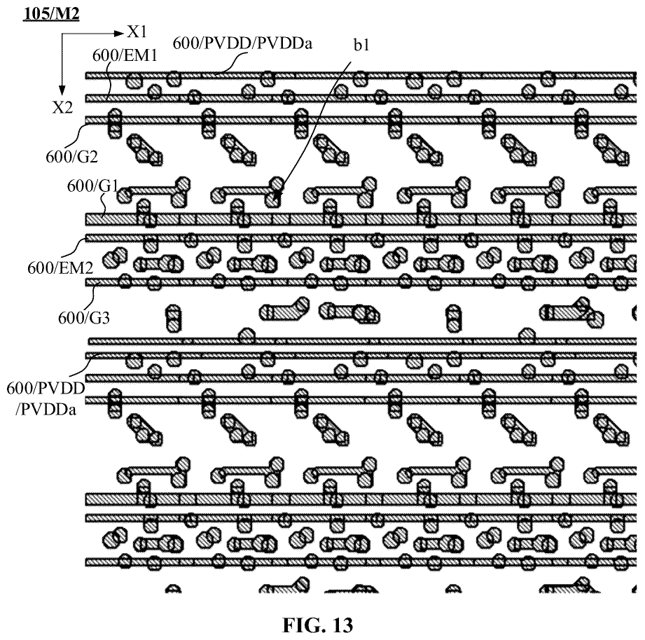

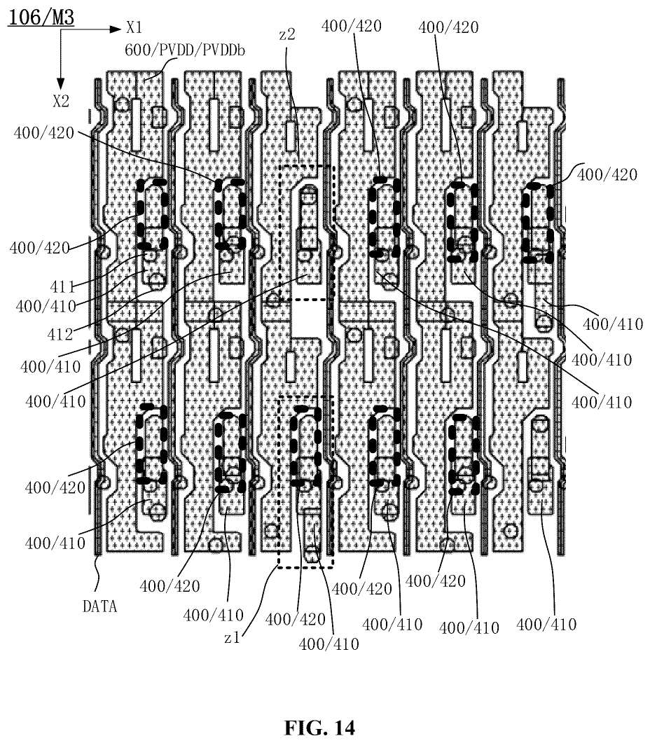

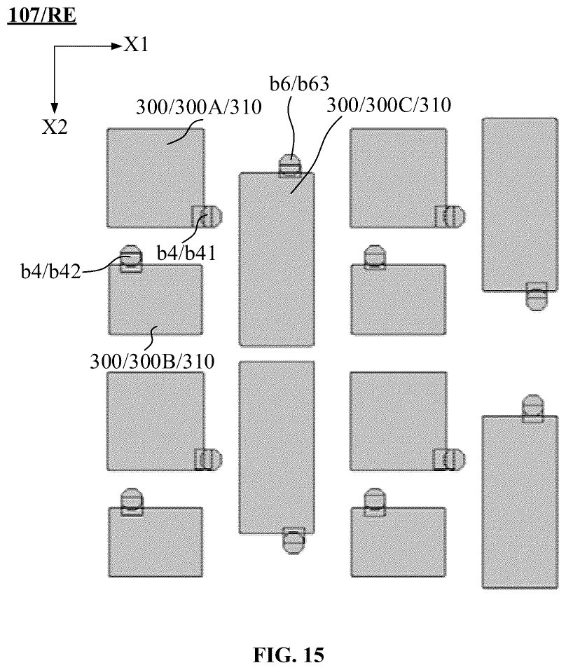

FIG. 6 is a diagram illustrating the structure of stacked film layers of a display panel according to embodiments of the present invention. FIG. 7 is a diagram illustrating part of the structure of the stacked film layers of FIG. 6. FIG. 8 is a diagram illustrating part of the structure of the stacked film layers of FIG. 6. FIG. 9 is a diagram illustrating the structure of the first part of film layers of FIG. 6. FIG. 10 is a diagram illustrating the structure of the second part of film layers of FIG. 6. FIG. 11 is a diagram illustrating the structure of the third part of film layers of FIG. 6. FIG. 12 is a diagram illustrating the structure of the fourth part of film layers of FIG. 6. FIG. 13 is a diagram illustrating the structure of the fifth part of film layers of FIG. 6. FIG. 14 is a first diagram illustrating the structure of the sixth part of film layers of FIG. 6. FIG. 15 is a diagram illustrating the structure of the seventh part of film layers of FIG. 6. See FIG. 6 to FIG. 15. If the pixel circuit 200 in the display panel 10 is the pixel circuit 200 shown in FIG. 2, the stacked film layer structure of the display panel 10 may be illustrated as that in FIG. 6. FIG. 6 may also be understood as a diagram illustrating the structure of film layers of region A of FIG. 1. FIG. 7 and FIG. 8 are each a diagram illustrating part of the structure of the stacked film layers of FIG. 6. With reference to FIG. 6 to FIG. 8, the position relationships between the stacked film layers can be clearly observed. FIG. 9 to FIG. 15 illustrate the different film layers of FIG. 6 from the bottom to the top. Different film layers are described later.

For the position arrangement of transistors in the pixel circuit 200 and the wiring arrangement for the electrical connection to the pixel circuit 200, reference may be made to FIG. 6 to FIG. 15. With reference to FIG. 14, in the z1 region of FIG. 14, the anode connection portion 400 includes a connection subportion 410 and a compensation subportion 420; and in the z2 region of FIG. 14, the anode connection portion 400 includes only a connection subportion 410. In other words, part of the anode connection portions 400 in the display panel 10 each include only a connection subportion 410 to ensure the electrical connection between the light-emitting element 300 and the pixel circuit 200. Meanwhile, part of the anode connection portions 400 in the display panel 10 each include both a compensation subportion 420 and a connection subportion 410, thereby ensuring the electrical connection between the light-emitting element 300 and the pixel circuit 200, increasing the overall area of the anode connection portion 400 through the compensation subportion 420, adjusting the overall projection area of the anode connection portion 400 on the substrate 100, and thus improving the flatness of the overall structure of the display panel 10.

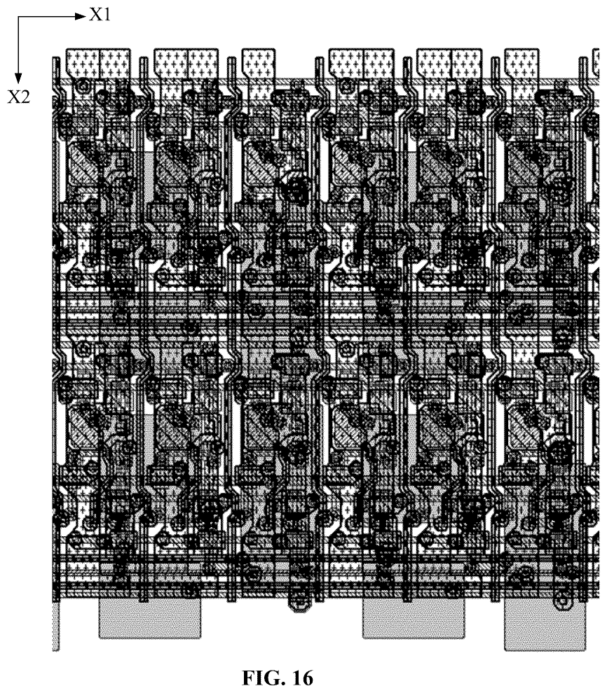

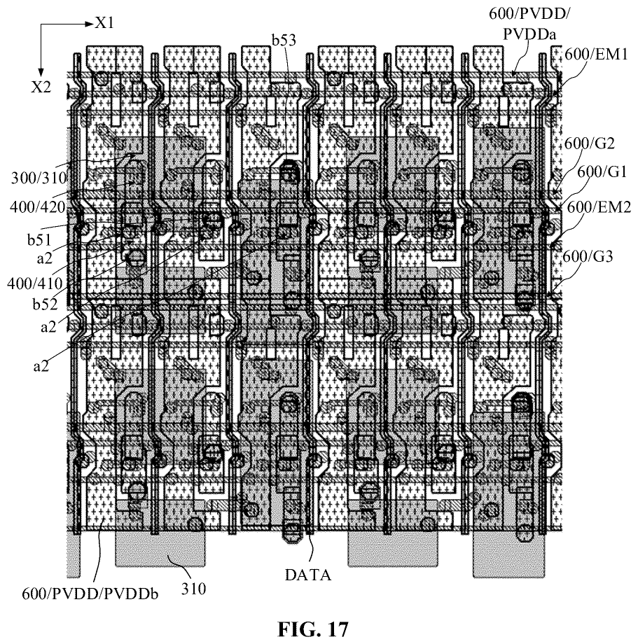

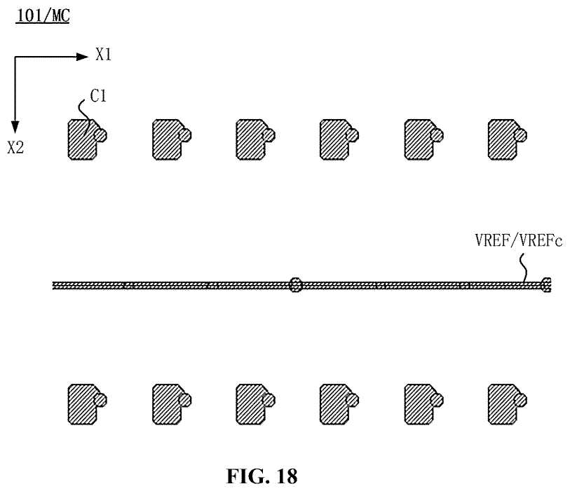

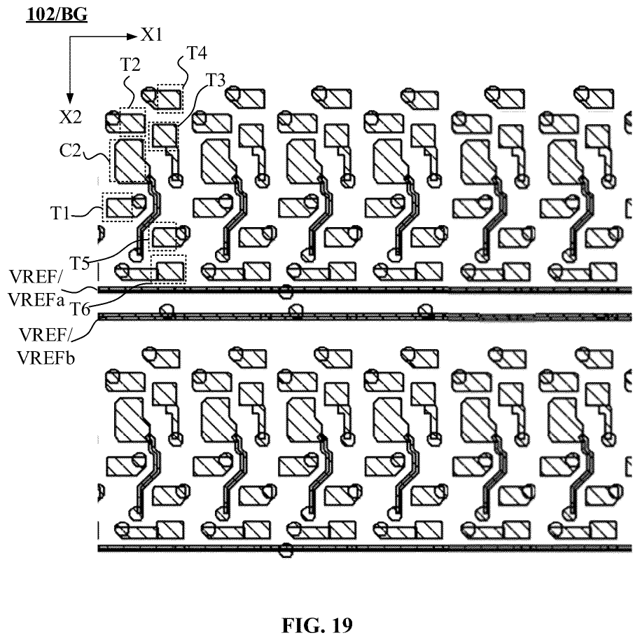

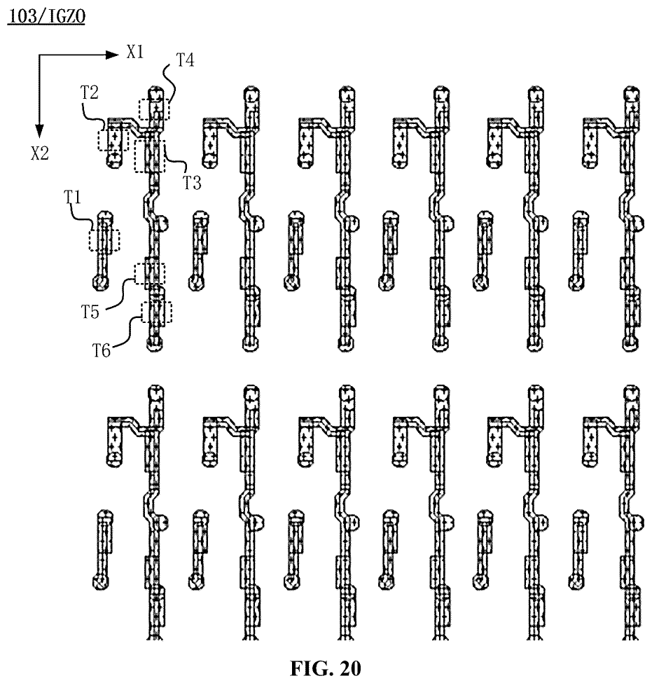

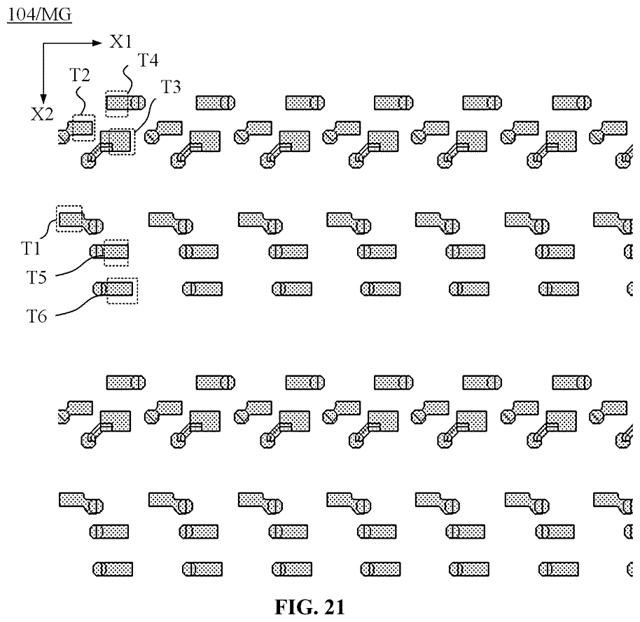

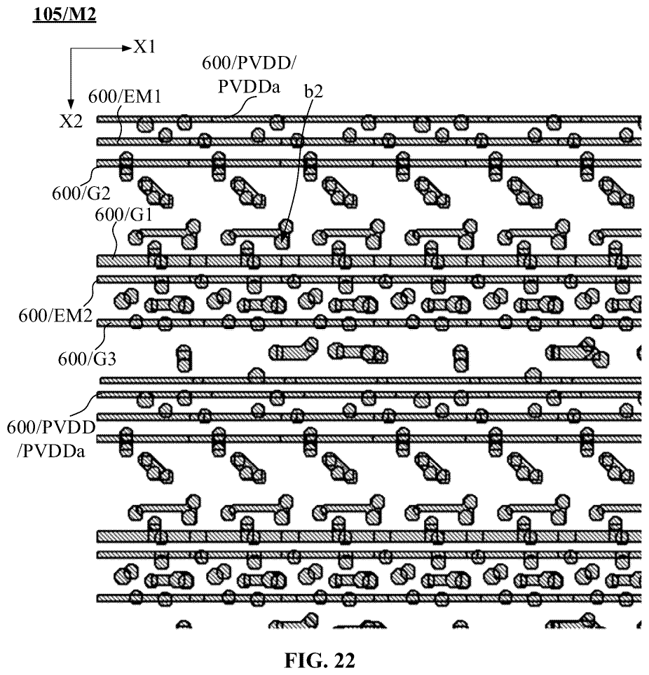

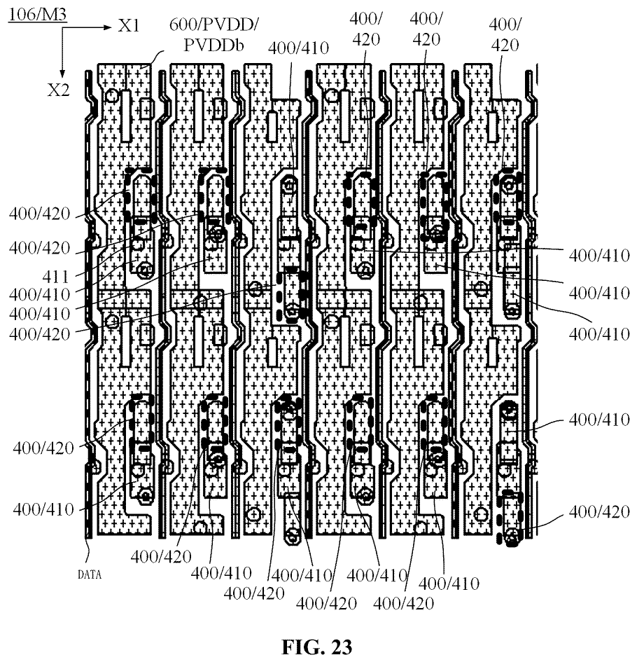

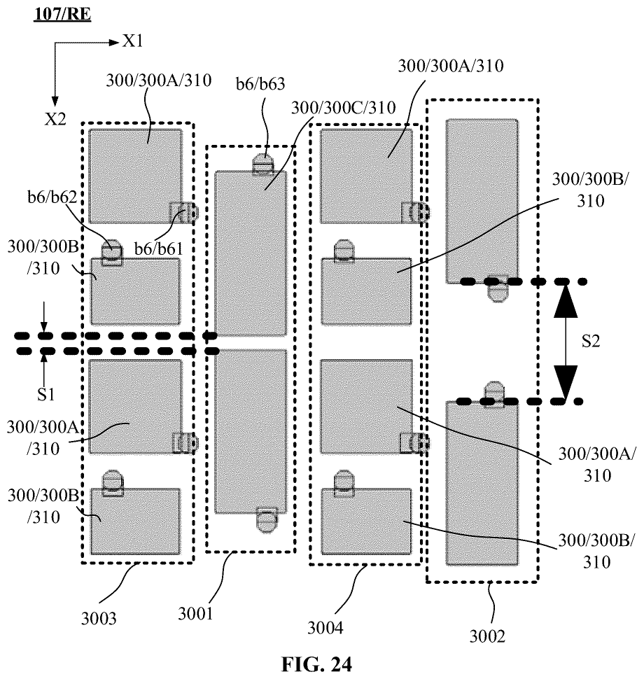

FIG. 16 is a diagram illustrating the structure of stacked film layers of a display panel according to embodiments of the present invention. FIG. 17 is a diagram illustrating part of the structure of the stacked film layers of FIG. 16. FIG. 18 is a diagram illustrating the structure of the first part of film layers of FIG. 16. FIG. 19 is a diagram illustrating the structure of the second part of film layers of FIG. 16. FIG. 20 is a diagram illustrating the structure of the third part of film layers of FIG. 16. FIG. 21 is a diagram illustrating the structure of the fourth part of film layers of FIG. 16. FIG. 22 is a diagram illustrating the structure of the fifth part of film layers of FIG. 16. FIG. 23 is a first diagram illustrating the structure of the sixth part of film layers of FIG. 16. FIG. 24 is a diagram illustrating the structure of the seventh part of film layers of FIG. 16. See FIG. 16 to FIG. 24. If the pixel circuit 200 in the display panel 10 is the pixel circuit 200 shown in FIG. 2, the stacked film layer structure of the display panel 10 may be illustrated as that in FIG. 16. FIG. 16 may also be understood as a diagram illustrating another structure of film layers of region A of FIG. 1. FIG. 17 is a diagram illustrating part of the structure of the stacked film layers of FIG. 16. With reference to FIG. 16 and FIG. 17, the position relationships between the stacked film layers can be clearly observed. FIG. 18 to FIG. 24 illustrate the different film layers of FIG. 16 from the bottom to the top. Different film layers are described later.

For the position arrangement of transistors in the pixel circuit 200 and the wiring arrangement for the electrical connection to the pixel circuit 200, reference may be made to FIG. 16 to FIG. 24. See FIG. 23. Each of the anode connection portions 400 in the display panel 10 includes both a compensation subportion 420 and a connection subportion 410, thereby ensuring the electrical connection between the light-emitting element 300 and the pixel circuit 200, increasing the overall area of the anode connection portion 400 through the compensation subportion 420, and thus improving the flatness of the overall structure of the display panel 10. Further, each anode connection portion 400 includes a compensation subportion 420, thereby ensuring a uniform structure of the display panel 10. It is also possible to ensure the same or similar light transmittance across different regions of the display panel 10, ensure a consistent optical effect across different regions of the display panel 10, and ensure the display effect of the display panel 10. Further, with reference to FIG. 14 and FIG. 23, the configuration of the compensation subportion 420 is flexible and can be adaptively adjusted to compensate the connection subportion 410 as required, thereby improving the overall display effect of the display panel 10.

In summary, the display panel of this embodiment of the present invention includes an anode connection portion located on the side of the anode facing the substrate, thereby increasing the overall area of the anode connection portion, ensuring the film layer flatness at the anode, and improving the overall flatness of the display panel. With the compensation subportion, it is possible to increase the overall area of the anode connection portion, ensure the same or similar light transmittance across different regions of the display panel 10, ensure a consistent optical effect across different regions of the display panel 10, and ensure the display effect of the display panel 10.

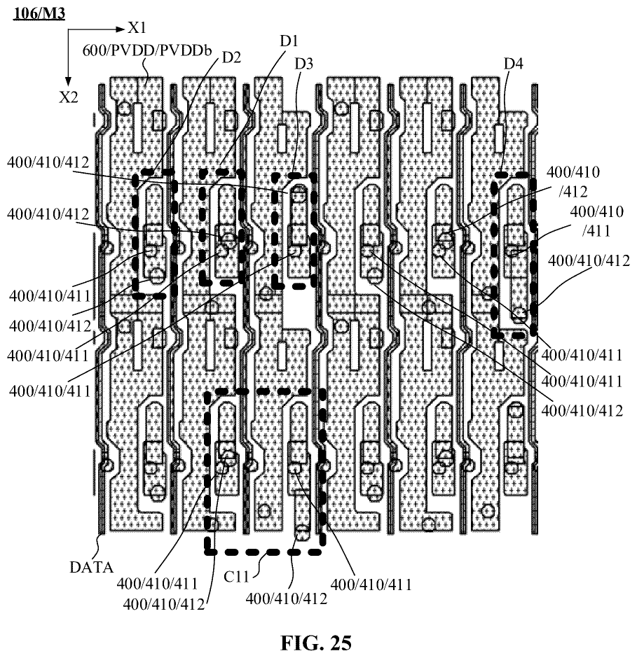

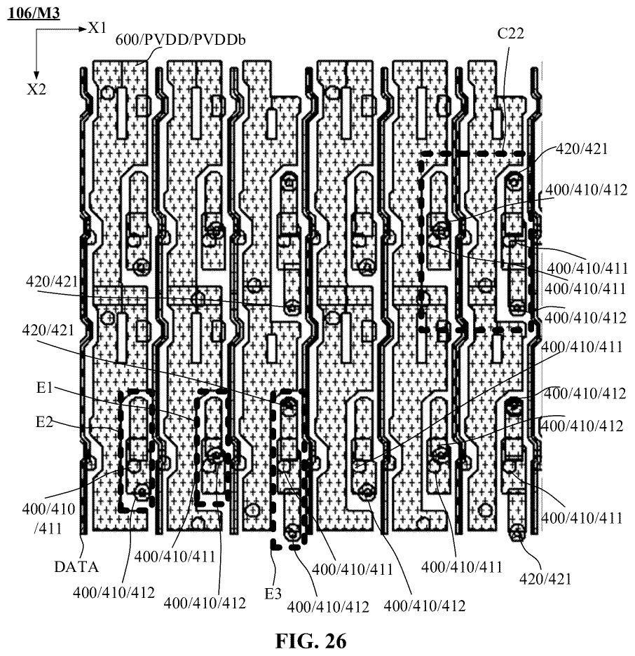

FIG. 25 is a second diagram illustrating the structure of the sixth part of film layers of FIG. 6. FIG. 26 is a second diagram illustrating the structure of the sixth part of film layers of FIG. 16. With continued reference to FIG. 6 to FIG. 26, the connection subportion 410 includes a pixel circuit connection terminal 411. The pixel circuit connection terminal 411 connects the connection subportion 410 and the pixel circuit 200. In two anode connection portions 400 arranged along the first direction X1, the two pixel circuit connection terminals 411 are arranged along the first direction X1. The first direction X1 is parallel to the plane where the substrate 100 is located.

Further, the connection subportion 410 includes a pixel circuit connection terminal 411. The connection subportion 410 is electrically connected to the pixel circuit 200 by the pixel circuit connection terminal 411, thereby achieving the electrical connection between the connection subportion 410 and the pixel circuit 200.

By way of example, referring to FIG. 8, the region indicated by the arrow a1 in FIG. 8 may be understood as that the connection subportion 410 is electrically connected to the pixel circuit 200 by the pixel circuit connection terminal 411. Further, referring to FIG. 13 and FIG. 14, the region indicated by the arrow b1 in FIG. 13 may be understood as the connection portion of the pixel circuit 200. The connection between the pixel circuit connection terminal 411 in FIG. 14 and the region indicated by the arrow b1 in FIG. 13 enables the connection between the pixel circuit 200 and the connection subportion 410. Similarly, referring to FIG. 17, the region indicated by the arrow a2 in FIG. 17 may be understood as that the connection subportion 410 is electrically connected to the pixel circuit 200 by the pixel circuit connection terminal 411. Further, referring to FIG. 22 and FIG. 23, the region indicated by the arrow b2 in FIG. 22 may be understood as the connection portion of the pixel circuit 200. The connection between the pixel circuit connection terminal 411 in FIG. 23 and the region indicated by the arrow b2 in FIG. 22 enables the connection between the pixel circuit 200 and the connection subportion 410.

Further, FIG. 25 shows the same film layer diagram as FIG. 14. To facilitate clear identification of the reference numerals, some of the reference numerals are shown in FIG. 25. Similarly, FIG. 26 shows the same film layer diagram as FIG. 23. To facilitate clear identification of the reference numerals, some of the reference numerals are shown in FIG. 26.

With reference to FIG. 8, in the two anode connection portions 400 arranged along the first direction X1, the connection subportions 410 of the two anode connection portions 400 are also arranged along the first direction X1. This reflects that the anode connection portions 400 and the pixel circuits 200 are disposed in an orderly manner, thereby ensuring the overall structural balance of the display panel 10. Specifically, referring to FIG. 25, in the two anode connection portions 400 arranged along the first direction X1 in FIG. 25, the pixel circuit connection terminals 411 are also arranged along the first direction X1. In addition, referring to FIG. 13, the connection portions (the region indicated by the arrow b1 in FIG. 13) (for electrically connecting the pixel circuit connection terminals 411) in the pixel circuits are also arranged along the first direction X1, thereby reflecting the orderliness of the overall structure of the display panel 10. This can reduce the manufacturing difficulty of the display panel 10. The orderly arrangement of the structures in the display panel 10 ensures a balanced display effect.

Similarly, with reference to FIG. 17, in the two anode connection portions 400 arranged along the first direction X1, the connection subportions 410 of the two anode connection portions 400 are also arranged along the first direction X1. This reflects that the anode connection portions 400 and the pixel circuits 200 are disposed in an orderly manner, thereby ensuring the overall structural balance of the display panel 10. Specifically, referring to FIG. 26, in the two anode connection portions 400 arranged along the first direction X1 in FIG. 26, the pixel circuit connection terminals 411 are also arranged along the first direction X1. In addition, referring to FIG. 22, the connection portions (the region indicated by the arrow b2 in FIG. 22) (for electrically connecting the pixel circuit connection terminals 411) in the pixel circuits are also arranged along the first direction X1, thereby reflecting the orderliness of the overall structure of the display panel 10. This can reduce the manufacturing difficulty of the display panel 10. The orderly arrangement of the structures in the display panel 10 ensures a balanced display effect.

With continued reference to FIG. 6 to FIG. 26, the connection subportion 410 includes an anode connection terminal 412. The anode connection terminal 412 connects the connection subportion 410 and the anode 310. In the two anode connection portions 400 arranged along the first direction X1, the two anode connection terminals 412 are staggered along the first direction X1. The first direction X1 is parallel to the plane where the substrate 100 is located.

Further, the connection subportion 410 includes an anode connection terminal 412. The connection subportion 410 is electrically connected to the light-emitting element 300 by the anode connection terminal 412, thereby achieving the electrical connection between the anode connection portion 400 and the light-emitting element 300.

By way of example, referring to FIG. 8, the regions indicated by arrows b31, b32, and b33 in FIG. 8 may be understood as that the corresponding connection subportions 410 are electrically connected to light-emitting elements 300 of different colors by anode connection terminals 412. Further, referring to FIG. 14 and FIG. 15, the region indicated by the arrow b4 in FIG. 15 may be understood as the connection portion at the light-emitting element 300, and the anode connection terminals 412 in different anode connection portions 400 in FIG. 14 are connected to connection portions (regions indicated by b4) corresponding to different light-emitting elements 300 in FIG. 15, thereby achieving the electrical connection between the light-emitting elements 300 and the anode connection portions 400. Similarly, referring to FIG. 17, the regions indicated by arrows b51, b52, and b53 in FIG. 17 may be understood as that the corresponding connection subportions 410 are electrically connected to light-emitting elements 300 of different colors by anode connection terminals 412. Further, referring to FIG. 23 and FIG. 24, the region indicated by the arrow b5 in FIG. 25 may be understood as the connection portion at the light-emitting element 300, and the anode connection terminals 412 in different anode connection portions 400 in FIG. 23 are connected to connection portions (regions indicated by b5) corresponding to different light-emitting elements 300 in FIG. 24, thereby achieving the electrical connection between the light-emitting elements 300 and the anode connection portions 400.

Further, with reference to FIG. 8, in the two anode connection portions 400 arranged along the first direction X1, the anode connection terminals 412 in the anode connection portions 400 are staggered along the first direction X1. See the region indicated by b31, the region indicated by b32, and the region indicated by b33 in FIG. 8. Specifically, referring to FIG. 15, the light-emitting element 300 includes a corresponding connection portion b4. b41, b42, and b42 may be understood as connection portions of light-emitting elements 300 of different colors and configured to connect anode connection portions 400. Referring to FIG. 15 and FIG. 25, the anode connection terminal 412 in the anode connection portion 400 in the region D1 in FIG. 25 is connected to the connection portion b41 of the light-emitting element 300 in FIG. 15, the anode connection terminal 412 in the anode connection portion 400 in the region D2 in FIG. 25 is connected to the connection portion b42 of the light-emitting element 300 in FIG. 15, and the anode connection terminal 412 in the anode connection portion 400 in the region D3 in FIG. 25 is connected to the connection portion b43 of the light-emitting element 300 in FIG. 15. Further, light-emitting elements 300 at different positions in FIG. 15 may have light emission effects of different colors, thereby achieving the color display effect of the display panel 10. Optionally, the light-emitting element 300 including the connection portion b41 in FIG. 15 may be a red light-emitting element, the light-emitting element 300 including the connection portion b42 in FIG. 15 may be a green light-emitting element, and the light-emitting element 300 including the connection portion b43 in FIG. 15 may be a blue light-emitting element. With reference to FIG. 8, FIG. 15, and FIG. 25, by making the two anode connection terminals 412 staggered along the first direction X1, it is possible to achieve the arrangement of the light-emitting elements 300 as shown in FIG. 15. In the arrangement of the light-emitting elements 300 as shown in FIG. 15, the light-emitting elements 300 of different colors can ensure the pixel resolution of the display panel in terms of the visual effect by pixel rendering or pixel borrowing, thereby improving the display effect of the display panel 10.

Similarly, with reference to FIG. 17, in the two anode connection portions 400 arranged along the first direction X1, the anode connection terminals 412 in the anode connection portions 400 are staggered along the first direction X1. See the region indicated by b51, the region indicated by b52, and the region indicated by b53 in FIG. 17. Specifically, referring to FIG. 24, the light-emitting element 300 includes a corresponding connection portion b6. b61, b62, and b62 may be understood as connection portions of light-emitting elements 300 of different colors and configured to connect anode connection portions 400. Referring to FIG. 24 and FIG. 26, the anode connection terminal 412 in the anode connection portion 400 in the region E1 in FIG. 26 is connected to the connection portion b61 of the light-emitting element 300 in FIG. 24, the anode connection terminal 412 in the anode connection portion 400 in the region E2 in FIG. 26 is connected to the connection portion b62 of the light-emitting element 300 in FIG. 24, and the anode connection terminal 412 in the anode connection portion 400 in the region E3 in FIG. 26 is connected to the connection portion b63 of the light-emitting element 300 in FIG. 24. Further, light-emitting elements 300 at different positions in FIG. 24 may have light emission effects of different colors, thereby achieving the color display effect of the display panel 10. Optionally, the light-emitting element 300 including the connection portion b61 in FIG. 24 may be a red light-emitting element, the light-emitting element 300 including the connection portion b62 in FIG. 24 may be a green light-emitting element, and the light-emitting element 300 including the connection portion b63 in FIG. 24 may be a blue light-emitting element. With reference to FIG. 17, FIG. 24, and FIG. 26, by making the two anode connection terminals 412 staggered along the first direction X1, it is possible to achieve the arrangement of the light-emitting elements 300 as shown in FIG. 15. In the arrangement of the light-emitting elements 300 as shown in FIG. 24, the light-emitting elements 300 of different colors can ensure the pixel resolution of the display panel in terms of the visual effect by pixel rendering or pixel borrowing, thereby improving the display effect of the display panel 10.

Further, with continued reference to FIG. 6 to FIG. 26, the connection subportion 410 also includes a pixel circuit connection terminal 411. The pixel circuit connection terminal 411 connects the connection subportion 410 and the pixel circuit 200. In the two anode connection portions 400 arranged along the first direction X1, the anode connection terminals 412 are located on different sides of the pixel circuit connection terminals 411.

Specifically, the pixel circuit connection terminal 411 in the connection subportion 410 is configured to achieve the electrical connection between the connection subportion 410 and the pixel circuit 200, and the anode connection terminal 412 in the connection subportion 410 is configured to achieve the electrical connection between the connection subportion 410 and the light-emitting element 300.

Further, in anode connection portions 400 disposed at different positions, pixel circuit connection terminals 411 and anode connection terminals 412 in connection subportions 410 are disposed in different manners.

Specifically, referring to FIG. 25, in the two anode connection portions 400 arranged along the first direction X1, the anode connection terminals 412 are located on different sides of the pixel circuit connection terminals 411. Correspondingly, referring to FIG. 25, in the two anode connection portions 400 arranged along the first direction X1 in the region C11, the pixel circuit connection terminals 411 are also arranged along the first direction X1. In this manner, with reference to FIG. 9 to FIG. 13, the orderliness of the film layer structure of the pixel circuit 200 is ensured. In FIG. 25, the two anode connection terminals 412 in the region C11 are located on two sides of the pixel circuit connection terminals 411 along the second direction X2. In this manner, with reference to FIG. 15, it is possible to achieve the arrangement of the light-emitting elements 300 as shown in FIG. 15, reflecting the display effect of the display panel 10.

Similarly, referring to FIG. 26, in the two anode connection portions 400 arranged along the first direction X1, the anode connection terminals 412 are located on different sides of the pixel circuit connection terminals 411. Correspondingly, referring to FIG. 26, in the two anode connection portions 400 arranged along the first direction X1 in the region C22, the pixel circuit connection terminals 411 are also arranged along the first direction X1. In this manner, with reference to FIG. 18 to FIG. 22, the orderliness of the film layer structure of the pixel circuit 200 is ensured. In FIG. 25, the two anode connection terminals 412 in the region C22 are located on two sides of the pixel circuit connection terminals 411 along the second direction X2. In this manner, with reference to FIG. 24, it is possible to achieve the arrangement of the light-emitting elements 300 as shown in FIG. 24, reflecting the display effect of the display panel 10.

With continued reference to FIG. 1 and FIG. 6 to FIG. 26, the connection subportion 410 includes a pixel circuit connection terminal 411 and an anode connection terminal 412; the pixel circuit connection terminal 411 connects the connection subportion 410 and the pixel circuit 200; the anode connection terminal 412 connects the connection subportion 410 and the anode 310; and the light-emitting elements 300 include first-color light-emitting elements 300A, second-color light-emitting elements 300B, and third-color light-emitting elements 300C. The emitted color of the first-color light-emitting element 300A, the emitted color of the second-color light-emitting element 300B, and the emitted color of the third-color light-emitting element 300C are different. In the anode connection portion 400 connected to the first-color light-emitting element 300A, the pixel connection terminal 411 is located on the side of the anode connection terminal 412 facing away from the compensation subportion 420. In the anode connection portion 400 connected to the second-color light-emitting element 300B or the third-color light-emitting element 300C, the pixel connection terminal 411 is located on the side of the anode connection terminal 412 facing the compensation subportion 420.

Referring to FIG. 6, FIG. 8, FIG. 15, FIG. 16, FIG. 17, and FIG. 24, specifically referring to FIG. 15 and FIG. 24, the display panel 10 includes multiple light-emitting elements 300. The light-emitting elements 300 include first-color light-emitting elements 300A, second-color light-emitting elements 300B, and third-color light-emitting elements 300C. The first-color light-emitting element 300A, the second-color light-emitting element 300B, and the third-color light-emitting element 300C have different emitted colors, thereby achieving the color display effect of the display panel 10. Optionally, the first-color light-emitting element 300A may be a red light-emitting element, the second-color light-emitting element 300B may be a green light-emitting element, and the third-color light-emitting element 300C may be a blue light-emitting element.

Further, the anode 310 of the first-color light-emitting element 300A, the anode 310 of the second-color light-emitting element 300B, and the anode of the third-color light-emitting element 300C are connected to different anode connection portions 400 so that different pixel circuits 200 drive light-emitting elements 300 of different colors to emit light for display.

Specifically, with reference to FIG. 14, FIG. 15, and FIG. 25, the anode connection terminal 412 in the anode connection portion 400 in the region D1 in FIG. 25 is electrically connected to the first-color light-emitting element 300A in FIG. 15, the anode connection terminal 412 in the anode connection portion 400 in the region D2 in FIG. 25 is electrically connected to the second-color light-emitting element 300B in FIG. 15, and the anode connection terminals 412 in the anode connection portions 400 in the regions D3 and D4 in FIG. 25 are electrically connected to third-color light-emitting elements 300C in FIG. 15. With reference to the region D1 in FIG. 14 and FIG. 25, in the anode connection portion 400 connected to the first-color light-emitting element 300A, the pixel connection terminal 411 is located on the side of the anode connection terminal 412 facing away from the compensation subportion 420. With reference to the region D2 in FIG. 14 and FIG. 25, in the anode connection portion 400 connected to the second-color light-emitting element 300B, the pixel connection terminal 411 is located on the side of the anode connection terminal 412 facing the compensation subportion 420. With reference to the region D4 in FIG. 14 and FIG. 25, in the anode connection portion 400 connected to the third-color light-emitting element 300C, the pixel connection terminal 411 is located on the side of the anode connection terminal 412 facing the compensation subportion 420.

Further, with reference to FIG. 23, FIG. 24, and FIG. 26, the anode connection terminal 412 in the anode connection portion 400 in the region E1 in FIG. 26 is electrically connected to the first-color light-emitting element 300A in FIG. 24, the anode connection terminal 412 in the anode connection portion 400 in the region E2 in FIG. 26 is electrically connected to the second-color light-emitting element 300B in FIG. 24, and the anode connection terminal 412 in the anode connection portion 400 in the region E3 in FIG. 26 is electrically connected to the third-color light-emitting element 300C in FIG. 24. With reference to the region E1 in FIG. 23 and FIG. 26, in the anode connection portion 400 connected to the first-color light-emitting element 300A, the pixel connection terminal 411 is located on the side of the anode connection terminal 412 facing away from the compensation subportion 420. With reference to the region E2 in FIG. 23 and FIG. 26, in the anode connection portion 400 connected to the second-color light-emitting element 300B, the pixel connection terminal 411 is located on the side of the anode connection terminal 412 facing the compensation subportion 420. With reference to the region E3 in FIG. 23 and FIG. 26, in the anode connection portion 400 connected to the third-color light-emitting element 300C, the pixel connection terminal 411 is located on the side of the anode connection terminal 412 facing the compensation subportion 420.

In this manner, anode connection portions 400 electrically connected to light-emitting elements 300 of different colors may differ in terms of the arrangement of the pixel circuit connection terminal 411 and the anode connection terminal 412 in the connection subportion 410, reflecting the arrangement flexibility of the anode connection portions 400.

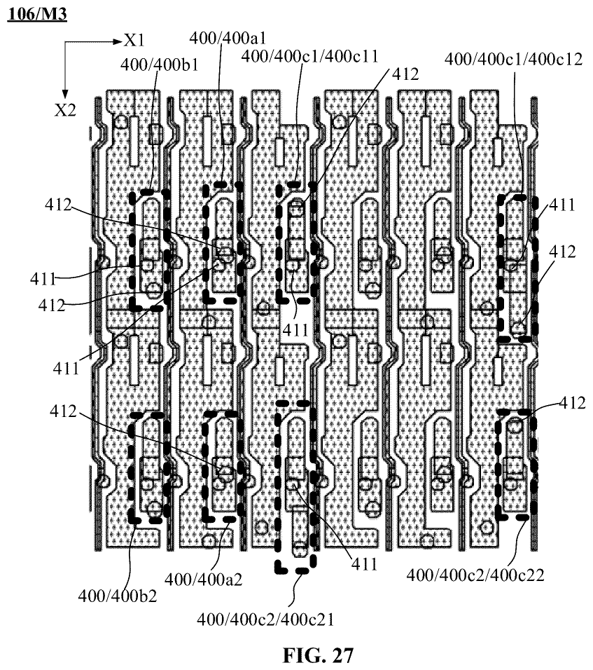

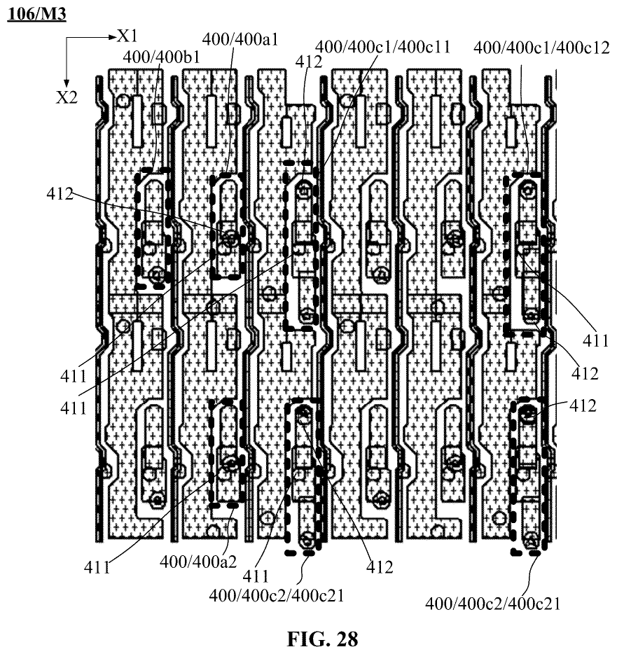

FIG. 27 is a third diagram illustrating the structure of the sixth part of film layers of FIG. 6. FIG. 28 is a third diagram illustrating the structure of the sixth part of film layers of FIG. 16. With continued reference to FIG. 1 and FIG. 6 to FIG. 28, the connection subportion 410 includes a pixel circuit connection terminal 411 and an anode connection terminal 412; the pixel circuit connection terminal 411 connects the connection subportion 410 and the pixel circuit 200; the anode connection terminal 412 connects the connection subportion 410 and the anode 310; and the light-emitting elements 300 include first-color light-emitting elements 300A, second-color light-emitting elements 300B, and third-color light-emitting elements 300C. The emitted color of the first-color light-emitting element 300A, the emitted color of the second-color light-emitting element 300B, and the emitted color of the third-color light-emitting element 300C are different. The two anode connection portions 400 connected to first-color light-emitting elements 300A and adjacent to each other along the second direction X2 include a first anode connection portion 400a1 and a second anode connection portion 400a2. The pixel circuit connection terminal 411 in the first anode connection portion 400a1 is located on the side facing the anode connection terminal 412 in the second anode connection portion 400a2. The second direction X2 is parallel to the plane where the substrate 100 is located. The two anode connection portions 400 connected to second-color light-emitting elements 300B and adjacent to each other along the second direction X2 include a third anode connection portion 400b1 and a fourth anode connection portion 400b2. The anode connection terminal 412 in the third anode connection portion 400b1 is located on the side facing the pixel circuit connection terminal 411 in the fourth anode connection portion 400b2. The two anode connection portions 400 connected to third-color light-emitting elements 300C and adjacent to each other along the second direction X2 include a fifth anode connection portion 400c1 and a sixth anode connection portion 400c2 . The pixel circuit connection terminal 411 in the fifth anode connection portion 400c1 is located on the side facing the pixel circuit connection terminal 411 in the sixth anode connection portion 400c2 . Alternatively, the anode connection terminal 412 in the fifth anode connection portion 400c1 is located on the side facing the anode connection terminal 412 in the sixth anode connection portion 400c2.

Further, FIG. 25 and FIG. 27 show the same film layer diagram as FIG. 14. To facilitate clear identification of the reference numerals, some of the reference numerals are shown in FIG. 25, and some of the reference numerals are shown in FIG. 27. Similarly, FIG. 28 and FIG. 26 show the same film layer diagram as FIG. 23. To facilitate clear identification of the reference numerals, some of the reference numerals are shown in FIG. 26, and some of the reference numerals are shown in FIG. 28.

Specifically, with reference to FIG. 15 and FIG. 27, the display panel 10 includes multiple anode connection portions 400 arranged along the second direction X2, the first anode connection portion 400a1 and the second anode connection portion 400a2 in FIG. 27 are adjacent to each other along the second direction X2, and the first anode connection portion 400a1 and the second anode connection portion 400a2 are both electrically connected to the anode 310 of the first-color light-emitting element 300A. The position of the pixel circuit connection terminal 411 in the first anode connection portion 400a1 is close to the position of the anode connection terminal 412 in the second anode connection portion 400a2. In other words, the first anode connection portion 400a1 and the second anode connection portion 400a2 are arranged along the second direction X2, where the terminals in the first anode connection portion 400a1 and the second anode connection portion 400a2 may be arranged in the following order along the second direction X2: the anode connection terminal 412 in the first anode connection portion 400a1, the pixel circuit connection terminal 411 in the first anode connection portion 400a1, the anode connection terminal 412 in the second anode connection portion 400a2, and the pixel circuit connection terminal 411 in the second anode connection portion 400a2. This is also the case with the terminals in the first anode connection portion 400a1 and the second anode connection portion 400a2 in FIG. 16, a diagram illustrating the structure of stacked film layers of the display panel 10. See FIG. 24 and FIG. 28. The details are not repeated here.

Specifically, with reference to FIG. 15 and FIG. 27, the display panel 10 includes multiple anode connection portions 400 arranged along the second direction X2, the third anode connection portion 400b1 and the fourth anode connection portion 400b2 in FIG. 27 are adjacent to each other along the second direction X2, and the third anode connection portion 400b1 and the fourth anode connection portion 400b2 are both electrically connected to the anode 310 of the second-color light-emitting element 300B. The anode connection terminal 412 in the third anode connection portion 400b1 is close to the pixel circuit connection terminal 411 in the fourth anode connection portion 400b2. In other words, the third anode connection portion 400b1 and the fourth anode connection portion 400b2 are arranged along the second direction X2, where the terminals of the third anode connection portion 400b1 and the fourth anode connection portion 400b2 may be disposed in the following order along the second direction X2: the pixel circuit connection terminal 411 in the third anode connection portion 400b1, the anode connection terminal 412 in the third anode connection portion 400b1, the pixel circuit connection terminal 411 in the fourth anode connection portion 400b2, and the anode connection terminal 412 in the fourth anode connection portion 400b2. This is also the case with the terminals in the third anode connection portion 400b1 and the fourth anode connection portion 400b2 in FIG. 16, a diagram illustrating the structure of stacked film layers of the display panel 10. See FIG. 24 and FIG. 28. The details are not repeated here.

Specifically, with reference to FIG. 15 and FIG. 27, the display panel 10 includes multiple anode connection portions 400 arranged along the second direction X2, the fifth anode connection portion 400c1 and the sixth anode connection portion 400c2 in FIG. 27 are adjacent to each other along the second direction X2, and the fifth anode connection portion 400c1 and the sixth anode connection portion 400c2 are both electrically connected to the anode of the third-color light-emitting element 300C. Referring to the fifth anode connection portion 400c1 (shown as 400c11 in the figure) and the sixth anode connection portion 400c2 (shown as 400c21 in the figure) in FIG. 27, the position of the pixel circuit connection terminal 411 in the fifth anode connection portion 400c1 is close to the position of the pixel circuit connection terminal 411 in the sixth anode connection portion 400c2 . In other words, the fifth anode connection portion 400c1 (shown as 400c11 in the figure) and the sixth anode connection portion 400c2 (shown as 400c21 in the figure) are arranged along the second direction X2, where the terminals of the fifth anode connection portion 400c1 (shown as 400c11 in the figure) and the sixth anode connection portion 400c2 (shown as 400c21 in the figure) may be disposed in the following order along the second direction X2: the anode connection terminal 412 in the fifth anode connection portion 400c1 (shown as 400c11 in the figure), the pixel circuit connection terminal 411 in the fifth anode connection portion 400c1 (shown as 400c11 in the figure), the pixel circuit connection terminal 411 in the sixth anode connection portion 400c2 (shown as 400c21 in the figure), and the anode connection terminal 412 in the sixth anode connection portion 400c2 (shown as 400c21 in the figure).

Alternatively, referring to the fifth anode connection portion 400c1 (shown as 400c12 in the figure) and the sixth anode connection portion 400c2 (shown as 400c21 in the figure) in FIG. 27, the position of the anode connection terminal 412 in the fifth anode connection portion 400c1 (shown as 400c12 in the figure) is close to the position of the anode connection terminal 412 in the sixth anode connection portion 400c2 (shown as 400c21 in the figure). In other words, the fifth anode connection portion 400c1 (shown as 400c12 in the figure) and the sixth anode connection portion 400c2 (shown as 400c22 in the figure) are arranged along the second direction X2, where the terminals of the fifth anode connection portion 400c1 (shown as 400c12 in the figure) and the sixth anode connection portion 400c2 (shown as 400c22 in the figure) may be disposed in the following order along the second direction X2: the pixel circuit connection terminal 411 in the fifth anode connection portion 400c1 (shown as 400c12 in the figure), the anode connection terminal 412 in the fifth anode connection portion 400c1 (shown as 400c12 in the figure), the anode connection terminal 412 in the sixth anode connection portion 400c2 (shown as 400c22 in the figure), and the pixel circuit connection terminal 411 in the sixth anode connection portion 400c2 (shown as 400c22 in the figure).

This is also the case with the terminals in the fifth anode connection portion 400c1 and the sixth anode connection portion 400c2 in FIG. 16, a diagram illustrating the structure of stacked film layers of the display panel 10. See FIG. 24 and FIG. 28. The details are not repeated here.

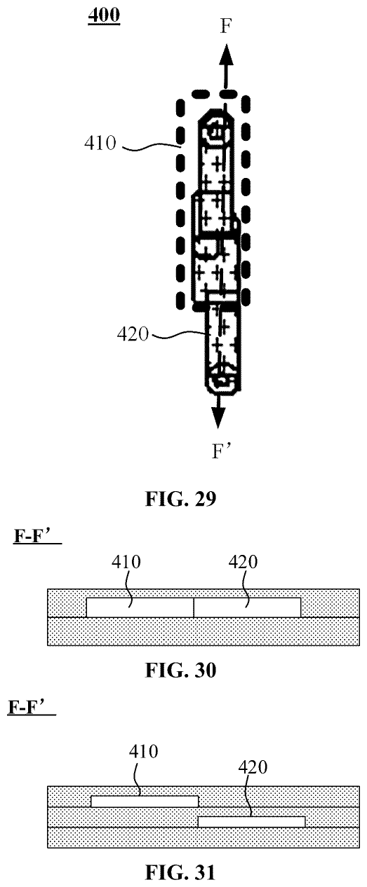

FIG. 29 is an enlarged view of an anode connection portion according to embodiments of the present invention. FIG. 30 is a first section view taken along line F-F′ of FIG. 29. The connection subportion 410 and the compensation subportion 420 are disposed in the same layer.

Specifically, the anode connection portion 400 includes a connection subportion 410 and a compensation subportion 420. Referring to FIG. 14 and FIG. 23, the positions of the connection subportion 410 and the compensation subportion 420 in the anode connection portion 400 are diverse and flexible. FIG. 29 is an enlarged view of an anode connection portion 400.

Further, with reference to FIG. 29 and FIG. 30, the connection subportion 410 and the compensation subportion 420 in the anode connection portion 400 may be disposed in the same layer, thereby avoiding adding an additional film layer for the compensation subportion 420 in the display panel 10, reducing the overall film layer thickness of the display panel 10, and facilitating the thin design of the display panel 10. It is also possible to ensure the same or similar light transmittance across different regions of the display panel 10, ensure a consistent optical effect across different regions of the display panel 10, and ensure the display effect of the display panel 10.

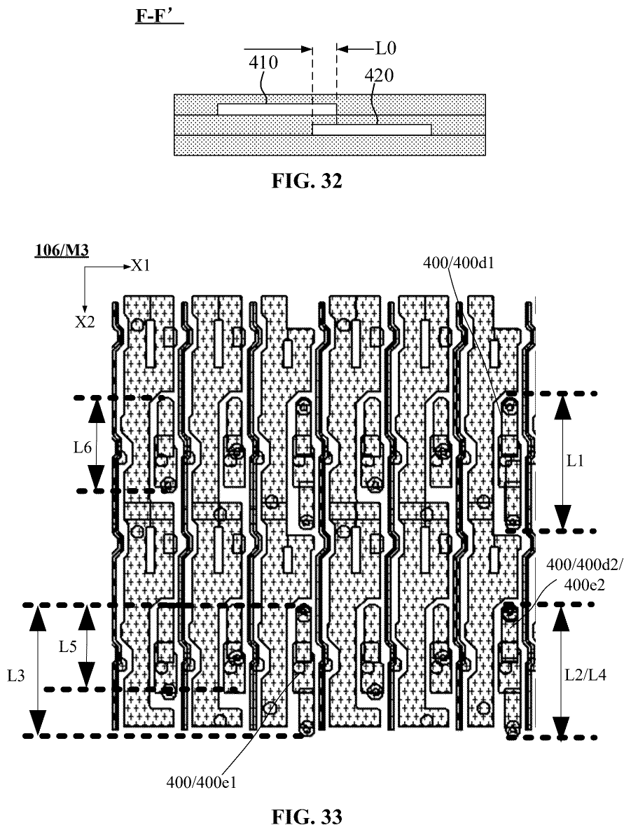

FIG. 31 is a first section view taken along line F-F′ of FIG. 29. FIG. 32 is a first section view taken along line F-F′ of FIG. 29. Referring to FIG. 29, FIG. 31, and FIG. 32, the connection subportion 410 and the compensation subportion 420 are disposed in different layers.

Further, in the anode connection portion 400, the positions of the connection subportion 410 and the compensation subportion 420 are flexible. With reference to FIG. 29, FIG. 31, and FIG. 32, the connection subportion 410 and the compensation subportion 420 in the anode connection portion 400 may be disposed in different layers. Further, with reference to FIG. 4, FIG. 5, and FIG. 31, in FIG. 31 and FIG. 32, the compensation subportion 420 is disposed on the side of the connection subportion 410 facing the substrate 100. Alternatively, the compensation subportion 420 may also be disposed on the side of the connection subportion 410 facing away from the substrate 100.

With continued reference to FIG. 29 and FIG. 32, along the thickness direction of the display panel 10, the connection subportion 410 partially overlaps the compensation subportion 420.

Further, when the connection subportion 410 and the compensation subportion 420 are disposed in different layers, the connection subportion 410 and the compensation subportion 420 may partially overlap along the thickness direction of the display panel 10. Specifically, referring to the region L0 in FIG. 32, at the region L0, along the thickness direction of the display panel 10, the connection subportion 410 overlaps the compensation subportion 420.

In general, the positions of the connection subportion 410 and the compensation subportion 420 in the anode connection portion 400 are diversified. See FIG. 30 to FIG. 32. The positions of the connection subportion 410 and the compensation subportion 420 in the anode connection portion 400 may be adaptively adjusted according to actual requirements.

FIG. 33 is a third diagram illustrating the structure of the sixth part of film layers of FIG. 16. Referring to FIG. 33, the anode connection portions 400 include a seventh anode connection portion 400d1 and an eighth anode connection portion disposed 400d2 along the second direction X2. The extension length L1 of the seventh anode connection portion 400d1 along the second direction X2 and the extension length L2 of the eighth anode connection portion 400d2 along the second direction X2 satisfy |L1−L2|/L1 ≤20%. The second direction X2 is parallel to the plane where the substrate 100 is located.

Similarly, FIG. 33, FIG. 28, and FIG. 26 show the same film layer diagram as FIG. 23. To facilitate clear identification of the reference numerals, some of the reference numerals are shown in FIG. 33.

Further, referring to FIG. 33, the display panel 10 includes multiple anode connection portions 400. The anode connection portion 400 includes a seventh anode connection portion 400d1 and an eighth anode connection portion 400d2 arranged along the second direction X2. The extension length of the seventh anode connection portion 400d1 along the second direction X2 is L1. The extension length of the eighth anode connection portion 400d2 along the second direction X2 is L2. L1 and L2 satisfy |L1−L2|/L1≤20%. L1 and L2 have the same or similar values.

Further, along the second direction X2, the extension length value of the seventh anode connection portion 400d1 is the same as or similar to the extension length value of the eighth anode connection portion 400d2. This reflects that the length of the anode connection portion 400 is uniform and reflects that the film layer structure of the film layer where the anode connection portion 400 is located is uniform. The uniformity of display of the display panel 10 and the display effect of the display panel 10 can be ensured by the balance of the film layer structure in the display panel 10.

Further, referring to FIG. 33, the seventh anode connection portion 400d1 and the eighth anode connection portion 400d2 are any two anode connection portions 400 arranged along the second direction X2.

Referring to FIG. 33, along the second direction X2, the extension length of the seventh anode connection portion 400d1 is the same as or similar to the extension length of the eighth anode connection portion 400d2, thereby ensuring the balance of the overall structure of the display panel 10.

Further, the seventh anode connection portion 400d1 and the eighth anode connection portion 400d2 may be two anode connection portions 400 adjacent to each other along the second direction X2 as shown in FIG. 33. Further, the seventh anode connection portion 400d1 and the eighth anode connection portion 400d2 may be two non-adjacent anode connection portions 400 along the second direction X2 in the display panel 10. In this manner, it can be understood that the extension lengths of any two anode connection portions 400 arranged along the second direction X2 are the same or similar, thereby better ensuring the balance of the overall structure of the display panel 10 and ensuring the overall display effect of the display panel 10.

With continued reference to FIG. 33, the seventh anode connection portion 400d1 and the eighth anode connection portion 400d2 have the same shape.

Further, referring to FIG. 33, the seventh anode connection portion 400d1 and the eighth anode connection portion 400d2 may have the same shape, thereby ensuring the balance of the anode connection portions 400 in the display panel 10 and improving the overall display effect of the display panel 10.

Specifically, the seventh anode connection portion 400d1 and the eighth anode connection portion 400d2 each include a connection subportion 410 and a compensation subportion 420. The shape of the seventh anode connection portion 400d1 may be understood as the overall shape formed by the connection subportion 410 and the compensation subportion 420 in the seventh anode connection portion 400d1. Similarly, the shape of the eighth anode connection portion 400d2 may be understood as the overall shape formed by the connection subportion 410 and the compensation subportion 420 in the eighth anode connection portion 400d2.

Referring to FIG. 33, the anode connection portions 400 include a ninth anode connection portion 400e1 and a tenth anode connection portion 400e2 arranged along the first direction X1 and connected to light-emitting elements of the same color. The first direction X1 is parallel to the plane where the substrate 100 is located. The extension length L3 of the ninth anode connection portion 400e1 along the second direction X2 and the extension length L4 of the tenth anode connection portion 400e2 along the second direction X2 satisfy |L3−L4|/L3 ≤20%. The second direction X2 is parallel to the plane where the substrate 100 is located and intersects the first direction X1.

Further, referring to FIG. 33, the display panel 10 includes multiple anode connection portions 400. The anode connection portion 400 includes a ninth anode connection portion 400e1 and a tenth anode connection portion 400e2 arranged along the first direction X1. The extension length of the ninth anode connection portion 400e1 along the second direction X2 is L3. The extension length of the tenth anode connection portion 400e2 along the second direction X2 is L4. L3 and L4 satisfy |L3−L4|/L3≤20%. L3 and L4 have the same or similar values.

Further, along the second direction X2, the extension length value of the ninth anode connection portion 400e1 is the same as or similar to the extension length value of the tenth anode connection portion 400e2. This reflects that the length of the anode connection portion 400 is uniform and reflects that the film layer structure of the film layer where the anode connection portion 400 is located is uniform. The uniformity of display of the display panel 10 and the display effect of the display panel 10 can be ensured by the balance of the film layer structure in the display panel 10.

With continued reference to FIG. 33, the ninth anode connection portion 400e1 and the tenth anode connection portion 400e2 have the same shape.

Further, referring to FIG. 33, the ninth anode connection portion 400e1 and the tenth anode connection portion 400e2 may have the same shape, thereby ensuring the balance of the anode connection portions 400 in the display panel 10 and improving the overall display effect of the display panel 10.

Specifically, the ninth anode connection portion 400e1 and the tenth anode connection portion 400e2 each include a connection subportion 410 and a compensation subportion 420. The shape of the ninth anode connection portion 400e1 may be understood as the overall shape formed by the connection subportion 410 and the compensation subportion 420 in the ninth anode connection portion 400e1. Similarly, the shape of the tenth anode connection portion 400e2 may be understood as the overall shape formed by the connection subportion 410 and the compensation subportion 420 in the tenth anode connection portion 400e2.

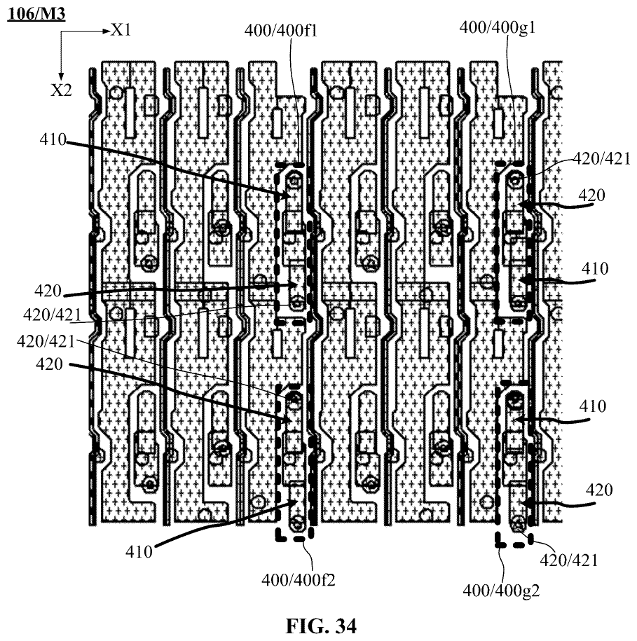

With continued reference to FIG. 1, FIG. 6 to FIG. 24, and FIG. 34, the light-emitting elements 300 include first-color light-emitting elements 300A, second-color light-emitting elements 300B, and third-color light-emitting elements 300C. The emitted color of the first-color light-emitting element 300A, the emitted color of the second-color light-emitting element 300B, and the emitted color of the third-color light-emitting element 300C are different. The extension length of the anode connection portion 400 connected to the first-color light-emitting element 300A or the second-color light-emitting element 300B along the second direction X2 is less than or equal to the extension length of the anode connection portion 400 connected to the third-color light-emitting element 300C along the second direction X2.

Specifically, referring to FIG. 1, FIG. 6, FIG. 15, FIG. 16, and FIG. 24, the display panel 10 includes multiple light-emitting elements 300 of different colors, specifically first-color light-emitting elements 300A, second-color light-emitting elements 300B, and third-color light-emitting elements 300C, thereby achieving the color display effect of the display panel 10. Optionally, the first-color light-emitting element 300A may be a red light-emitting element, the second-color light-emitting element 300B may be a green light-emitting element, and the third-color light-emitting element 300C may be a blue light-emitting element.

Further, referring to FIG. 16 to FIG. 24, the extension length, along the second direction X2, of the anode connection portion 400 connected to the first-color light-emitting element 300A or the second-color light-emitting element 300B is less than or equal to the extension length, along the second direction X2, of the anode connection portion 400 connected to the third-color light-emitting element 300C. Specifically, referring to FIG. 33, the extension length of the anode connection portion 400 connected to the first-color light-emitting element 300A along the second direction X2 is L5, the extension length of the anode connection portion 400 connected to the second-color light-emitting element 300B along the second direction X2 is L6, and the extension length of the anode connection portion 400 connected to the third-color light-emitting element 300C along the second direction X2 is L1. L5 is less than or equal to L1. L6 is also less than or equal to L1. FIG. 33 illustrates an example in which L6 is less than L1, and L5 is less than L1. By adjusting the extension length of the anode connection portion 400 along the second direction X2, it is possible to adaptively adjust the size of the anode 310 later, thereby ensuring that the extension length of the anode 310 of the third-color light-emitting element 300C along the second direction X2 is greater than that of the light-emitting elements 300 of other colors and facilitating the arrangement of the light-emitting elements 300 as shown in FIG. 24. In this manner, light-emitting elements 300 of different colors can ensure the pixel resolution of the display panel in terms of the visual effect by pixel rendering or pixel borrowing, thereby improving the display effect of the display panel 10.

With continued reference to FIG. 1 and FIG. 16 to FIG. 24, the display panel 10 includes multiple repetitive light-emitting element groups disposed in an array. Each repetitive light-emitting element group includes a first light-emitting element column 3001 and a second light-emitting element column 3002 arranged along the second direction X2. Each of the first light-emitting element column 3001 and the second light-emitting element column 3002 includes two third-color light-emitting elements 300C arranged along the second direction X2. A first spacing S1 is provided between the two third-color light-emitting elements 30C in the first light-emitting element column 3001. A second spacing S2 is provided between the two third-color light-emitting elements 30C in the second light-emitting element column 3002. The first spacing S1 is less than the second spacing S2. The second direction X2 intersects the first direction X1. The display panel 10 also includes an auxiliary structure. Along the thickness direction of the display panel 10, the auxiliary structure overlaps the second spacing.

The display panel 10 includes repetitive light-emitting element groups. The repetitive light-emitting element group includes multiple light-emitting elements 300 of different colors. The repetitive light-emitting element groups are disposed in an array in the display panel 10 to achieve the overall display effect of the display panel 10. The repetitive light-emitting element group may also be understood as the smallest repetitive unit of the light-emitting elements 300 arranged in the display panel 10. The repetitive light-emitting element group may refer to the region A in FIG. 1. FIG. 24 may be understood as a diagram illustrating the arrangement of anodes 310 of light-emitting elements 300 within one repetitive light-emitting element group.

Further, referring to FIG. 1 and FIG. 24, in one repetitive light-emitting element group, a first light-emitting element column 3001 and a second light-emitting element column 3002 are included. The first light-emitting element column 3001 includes two third-color light-emitting elements 300C (shown as anodes 310 of third-color light-emitting elements 300C in FIG. 24) arranged along the second direction X2. The second light-emitting element column 3002 also includes two third-color light-emitting elements 300C (shown as anodes 310 of third-color light-emitting elements 300C in FIG. 24) arranged along the second direction X2. Specifically, referring to FIG. 24, a first spacing S1 is provided between the two third-color light-emitting elements 300C in the first light-emitting element column 3001, and a second spacing S2 is provided between the two third-color light-emitting elements 300C in the second light-emitting element column 3002. S1 is greater than S2.

Further, the display panel 10 also includes an auxiliary structure. The auxiliary structure may be a support column for ensuring the overall structural stability of the display panel 10, or the auxiliary structure may be a light-transmissive hole for achieving fingerprint recognition or infrared sensing of the display panel 10. The type of the auxiliary structure may be adjusted according to actual requirements. In the repetitive light-emitting element group, the spacing between the two third-color light-emitting elements 300C in the second light-emitting element column 3002 is relatively large, and the auxiliary structure of the display panel 10 may overlap the second spacing S2 along the thickness direction of the display panel 10, so that the auxiliary structure can be added to the display panel 10 without affecting the arrangement of the light-emitting elements 300 of the display panel 10, thereby ensuring the overall effect of the display panel 10.

FIG. 34 is a fourth diagram illustrating the structure of the sixth part of film layers of FIG. 16. Referring to FIG. 1, FIG. 16 to FIG. 24, and FIG. 34, the two anode connection portions 400 connected to the two third-color light-emitting elements 300C in the first light-emitting element column 3001 include an eleventh anode connection portion 400f1 and a twelfth anode connection portion 400f2; and the two anode connection portions 400 connected to the two third-color light-emitting elements 300C in the second light-emitting element column 3002 include a thirteenth anode connection portion 400g1 and a fourteenth anode connection portion 400g2. In the eleventh anode connection portion 400f1, the compensation subportion 420 is located on the side of the connection subportion 410 facing the twelfth anode connection portion 400f2. In the twelfth anode connection portion 400f2, the compensation subportion 420 is located on the side of the connection subportion 410 facing the eleventh anode connection portion 400f1. In the thirteenth anode connection portion 400g1, the compensation subportion 420 is located on the side of the connection subportion 410 facing away from the fourteenth anode connection portion 400g2. In the fourteenth anode connection portion 400g2, the compensation subportion 420 is located on the side of the connection subportion 410 facing away from the thirteenth anode connection portion 400g1.

FIG. 34, FIG. 33, FIG. 28, and FIG. 26 show the same film layer diagram as FIG. 23. To facilitate clear identification of the reference numerals, some of the reference numerals are shown in FIG. 34.

Referring to FIG. 16, FIG. 17, FIG. 24, and FIG. 34, the two anode connection portions 400 connected to the two third-color light-emitting elements 300C in the first light-emitting element column 3001 include an eleventh anode connection portion 400f1 and a twelfth anode connection portion 400f2. The eleventh anode connection portion 400f1 and the twelfth anode connection portion 400f2 are also arranged along the second direction X2. With reference to FIG. 23 and FIG. 33, in the eleventh anode connection portion 400f1, the compensation subportion 420 is located on the side of the connection subportion 410 facing the twelfth anode connection portion 400f2; and in the twelfth anode connection portion 400f2, the compensation subportion 420 is located on the side of the connection subportion 410 facing the eleventh anode connection portion 400f1. That is, along the second direction X2, the eleventh anode connection portion 400f1 and the twelfth anode connection portion 400f2 are arranged in sequence along the second direction X2. Specifically, the connection subportion 410 of the eleventh anode connection portion 400f1, the compensation subportion 420 of the eleventh anode connection portion 400f1, the compensation subportion 420 of the twelfth anode connection portion 400f2, and the connection subportion 410 of the twelfth anode connection portion 400f2 are arranged in sequence.

Referring to FIG. 16, FIG. 17, FIG. 24, and FIG. 34, the two anode connection portions 400 connected to the two third-color light-emitting elements 300C in the second light-emitting element column 3002 include a thirteenth anode connection portion 400g1 and a fourteenth anode connection portion 400g2. The thirteenth anode connection portion 400g1 and the fourteenth anode connection portion 400g2 are also arranged along the second direction X2. With reference to FIG. 23 and FIG. 33, in the thirteenth anode connection portion 400g1, the compensation subportion 420 is located on the side of the connection subportion 410 facing away from the fourteenth anode connection portion 400g2; and in the fourteenth anode connection portion 400g2, the compensation subportion 420 is located on the side of the connection subportion 410 facing away from the thirteenth anode connection portion 400g1. That is, along the second direction X2, the thirteenth anode connection portion 400g1 and the fourteenth anode connection portion 400g2 are arranged in sequence along the second direction X2. Specifically, the connection subportion 420 of the thirteenth anode connection portion 400g1, the compensation subportion 410 of the thirteenth anode connection portion 400g1, the connection subportion 410 of the fourteenth anode connection portion 400g2, and the compensation subportion 420 of the fourteenth anode connection portion 400g2 are arranged in sequence.

Referring to FIG. 1, FIG. 16 to FIG. 24, FIG. 26, and FIG. 34, the connection subportion 410 includes an anode connection terminal 412. The anode connection terminal 412 connects the connection subportion 410 and the anode 310. Moreover, the compensation subportion 420 includes a virtual anode connection terminal 421. The virtual anode connection terminal 421 in the eleventh anode connection portion 400f1 is disposed in correspondence with the anode connection terminal 412 in the twelfth anode connection portion 400f2. The virtual anode connection terminal 421 in the twelfth anode connection portion 400f2 is disposed in correspondence with the anode connection terminal 412 in the eleventh anode connection portion 400f1. The virtual anode connection terminal 421 in the thirteenth anode connection portion 400g1 is disposed in correspondence with the anode connection terminal 412 in the fourteenth anode connection portion 400g2. The virtual anode connection terminal 421 in the fourteenth anode connection portion 400g2 is disposed in correspondence with the anode connection terminal 412 in the thirteenth anode connection portion 400g1.

Further, referring to FIG. 26, the connection subportion 410 of the anode connection portion 400 includes a pixel circuit connection terminal 411 and an anode connection terminal 412. Referring to FIG. 26 and FIG. 34, the compensation subportion 420 of the anode connection portion 400 includes a virtual anode connection terminal 421. The added virtual anode connection terminal 421 ensures the balance of the arrangement of the connection terminals in the overall structure of the anode connection portion 400, thereby ensuring the balance of the arrangement of the connection terminals in the display panel 10, reducing the manufacturing difficulty of the display panel 10, and reducing the manufacturing costs of the display panel 10.

Referring to FIG. 26 and FIG. 34, the virtual anode connection terminal 421 in the eleventh anode connection portion 400f1 is disposed in correspondence with the anode connection terminal 412 in the twelfth anode connection portion 400f2; and the virtual anode connection terminal 421 in the twelfth anode connection portion 400f2 is disposed in correspondence with the anode connection terminal 412 in the eleventh anode connection portion 400f1. In other words, along the second direction X2, the connection terminals in the eleventh anode connection portion 400f1 are arranged in sequence as follows: the anode connection terminal 412, the pixel circuit connection terminal 411, and the virtual anode connection terminal 421; and along the second direction X2, the connection terminals in the twelfth anode connection portion 400f2 are arranged in sequence as follows: the virtual anode connection terminal 421, the pixel circuit connection terminal 411, and the anode connection terminal 412. This can be understood as that the arrangement order of the connection terminals in the eleventh anode connection portion 400f1 and the connection terminals in the twelfth anode connection portion 400f2 are exactly opposite.

Further, referring to FIG. 26 and FIG. 34, the virtual anode connection terminal 421 in the thirteenth anode connection portion 400g1 is disposed in correspondence with the anode connection terminal 412 in the fourteenth anode connection portion 400g2; and the virtual anode connection terminal 421 in the fourteenth anode connection portion 400g2 is disposed in correspondence with the anode connection terminal 412 in the thirteenth anode connection portion 400g1. In other words, along the second direction X2, the connection terminals in the thirteenth anode connection portion 400g1 are arranged in sequence as follows: the virtual anode connection terminal 421, the pixel circuit connection terminal 411, and the anode connection terminal 412; and along the second direction X2, the connection terminals in the fourteenth anode connection portion 400g2 are arranged in sequence as follows: the anode connection terminal 412, the pixel circuit connection terminal 411, and the virtual anode connection terminal 421. This can be understood as that the arrangement order of the connection terminals in the thirteenth anode connection portion 400g1 and the connection terminals in the fourteenth anode connection portion 400g2 are exactly opposite.

With continued reference to FIG. 16 to FIG. 24, along the thickness direction of the display panel 10, the anode 310 of the third-color light-emitting element 300C at least partially overlaps the anode connection portion 400 electrically connected thereto.

Further, referring to FIG. 17, FIG. 23, and FIG. 24, along the thickness direction of the display panel 10, the anode 310 of the third-color light-emitting element 300C at least partially overlaps the anode connection portion 400 electrically connected thereto, or the anode 310 covers at least part of the anode connection portion 400 electrically connected thereto.

Further, the anode 310 covers the anode connection portion 400 electrically connected to the anode 310, and the area of the anode connection portion 400 is increased by the compensation subportion 420 of the anode connection portion 400, thereby ensuring that the entire light-emitting element 300 is similarly padded, avoiding color cast or dispersion, and thus ensuring the display effect of the display panel 10.

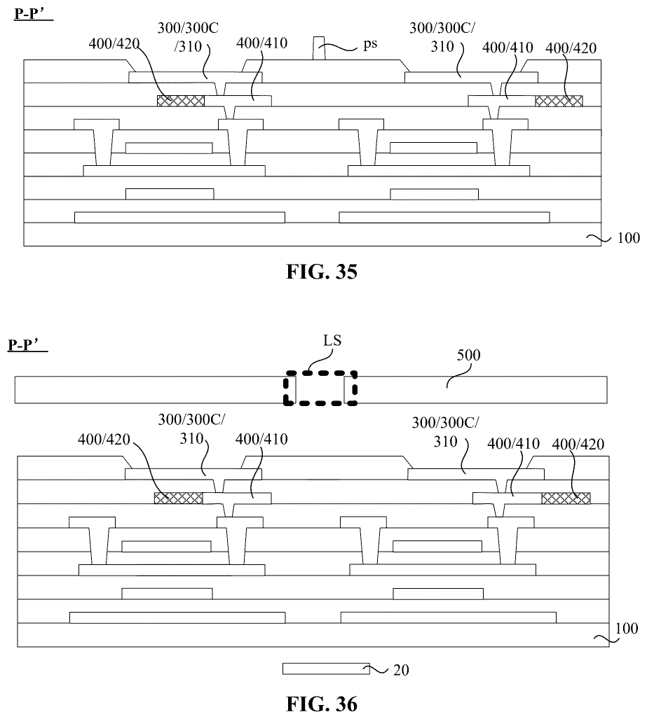

FIG. 35 is a first section view taken along line P-P′ of FIG. 1. Referring to FIG. 35, the auxiliary structure includes a support column ps.

The auxiliary structure may include a support column ps. The support column ps is configured to support the film layer structure of the display panel 10 to ensure the stability of the overall structure of the display panel 10. The support column ps may be disposed independently or may be integrally formed with other film layers. This is not limited in embodiments of the present application.

As shown in FIG. 1, FIG. 24, and FIG. 35, in order not to affect the light emission and display of the display panel, the orthographic projection of the support column on the film layer where the anode connection portion is located is located at the second spacing.

Specifically, the support column is disposed between the anode and the substrate; and/or the support column is disposed on the side of the anode facing away from the substrate.

Specifically, the position of the support column is flexible. The support column may be disposed between the anode 310 and the substrate 100; or referring to FIG. 35, the support column is disposed on the side of the anode 310 facing away from the substrate 100; or some support columns are disposed between the anode 310 and the substrate 100, and some support columns are disposed on the side of the anode 310 facing away from the substrate 100. The position of the support column can be adaptively adjusted according to actual requirements.

FIG. 36 is a second section view taken along line P-P′ of FIG. 1. With reference to FIG. 1, FIG. 24, and FIG. 36, the auxiliary structure includes a light-transmissive hole LS.

Further, the auxiliary structure may include a light-transmissive hole LS. The display panel is provided with the light-transmissive hole LS, and the light-transmissive hole LS at least partially overlaps the optical sensor 20 along the thickness direction of the display panel, so that the display panel 10 can collect and determine the external light. Specifically, the light-transmissive hole LS in the display panel 10 can ensure that light is incident to the optical sensor 20 through the light-transmissive hole LS, thereby ensuring that the optical sensor 20 can perform information sensing according to the sensed optical information. For example, the optical sensor 20 may be a light sensor. In a plan view, the light sensor overlaps the light-transmissive hole LS. The visible light can pass through the light-transmissive hole so that the light sensor can adjust the screen brightness of the display device according to the brightness of the surrounding light. Alternatively, the light sensor may be an infrared light sensor or a fingerprint recognition sensor. Fingerprint information or palmprint information can be incident to the fingerprint recognition sensor through the light-transmissive hole so that the processing chip in the display panel can perform a corresponding operation according to the fingerprint information or the palmprint information sensed by the fingerprint sensor.

Further, with reference to FIG. 1, FIG. 24, and FIG. 36, in order not to affect the normal light emission of light-emitting elements 300, the light-transmissive hole LS may be disposed between the light-emitting elements 300. Specifically, the orthographic projection of the light-transmissive hole LS on the film layer where the anode connection portion 400 is located is located at the second spacing L2.

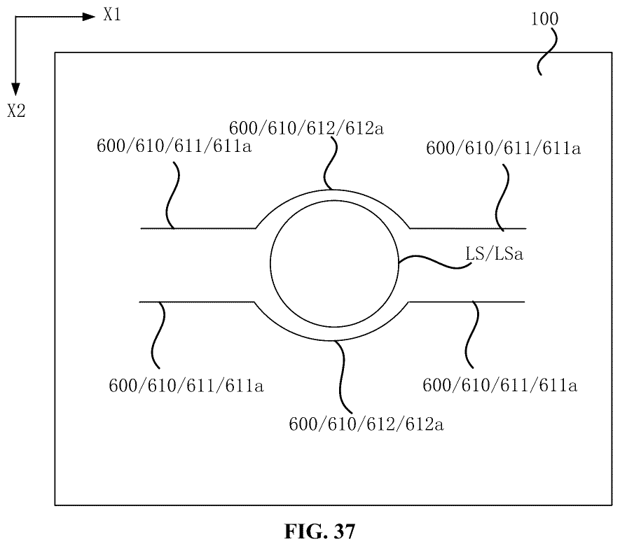

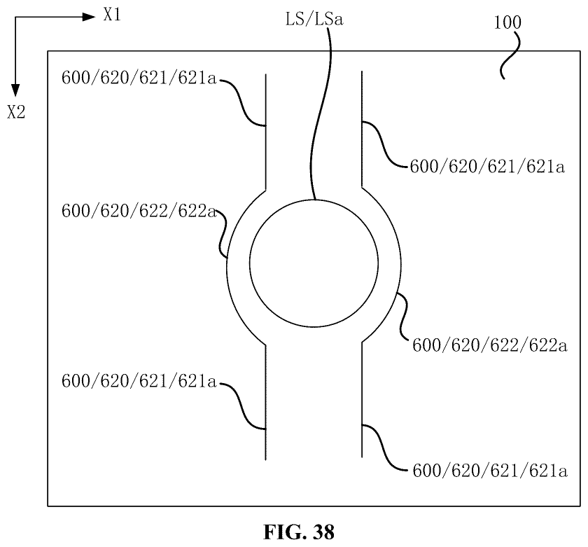

FIG. 37 is a diagram illustrating the orthographic projections of a light-transmissive hole and signal lines on a substrate according to embodiments of the present invention. FIG. 38 is a diagram illustrating the orthographic projections of a light-transmissive hole and signal lines on a substrate according to embodiments of the present invention. Referring to FIG. 36 to FIG. 38, the display panel 10 also includes a light-shielding layer 500 located on the side of the light-emitting element 300 facing away from the pixel circuit 200. The light-shielding layer 500 is provided with a light-transmissive hole LS. The display panel 10 also includes multiple signal lines located between the substrate 100 and the light-shielding layer 500. The light-transmissive hole LS does not overlap the signal line 600 along the thickness direction of the display panel 10.

Specifically, referring to FIG. 36, the display panel 10 also includes a light-shielding layer 500. The light-shielding layer 500 is located on the side of the light-emitting element 300 facing away from the pixel circuit 200. The light-transmissive hole LS in the display panel 10 is disposed in the light-shielding layer 500, thereby facilitating the fingerprint recognition function or the infrared sensing function of the display panel 10.

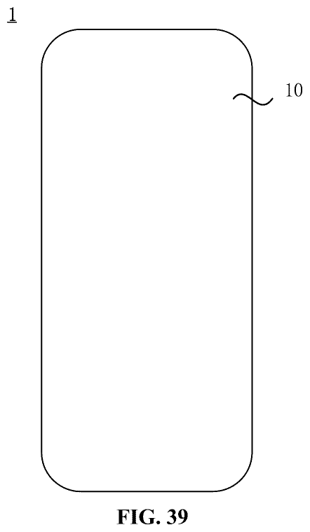

Further, the signal lines 600 in the display panel 10 are disposed between the light-shielding layer 600 and the substrate 100 to achieve signal transmission. Referring to FIG. 38 and FIG. 39, along the thickness direction of the display panel 10, the light-transmissive hole LS does not overlap the signal line 600. In other words, the signal line 600 avoids the light-transmissive hole LS when being transmitted to the vicinity of the light-transmissive hole LS. This ensures that the signal line 600 does not block light transmitted in the light-transmissive hole LS and avoids that the signal line 600 interferes with light transmitted in the light-transmissive hole LS. For example, diffraction is avoided. Therefore, by adjusting the signal line 600 near the light-transmissive hole LS, it is possible to ensure the light transmittance of the display panel 10.

With continued reference to FIG. 36 to FIG. 38, the signal lines 600 include first signal lines 610, the first signal lines 610 each include a first body portion 611 and a first winding portion 612 connected to each other, the orthographic projection of the first body portion 611 on the plane where the substrate 100 is located is a first body portion projection 611a, the orthographic projection of the first winding portion 612 on the plane where the substrate 100 is located is a first winding portion projection 612a, the orthographic projection of the light-transmissive hole LS on the plane where the substrate 100 is located is a light-transmissive hole projection LSa, the first body portion projection 611a extends along the first direction X1, the straight line where the first body portion projection 611a is located overlaps the light-transmissive hole projection LSa, the first winding portion projection 612a overlaps the light-transmissive hole projection LSa along the second direction X2, the second direction X2 intersects the first direction X1, and projections of first winding portions 612a of two of the first signal lines 610 are located on two opposite sides of the light-transmissive hole projection LSa along the second direction X2.

Moreover/alternatively, the signal lines 600 include second signal lines 620, the second signal lines 620 each include a second body portion 621 and a second winding portion 622 connected to each other, the orthographic projection of the second body portion 621 on the plane where the substrate 100 is located is a second body portion projection 621a, the orthographic projection of the second winding portion 622 on the plane where the substrate 100 is located is a second winding portion projection 622a, the orthographic projection of the light-transmissive hole LS on the plane where the substrate 100 is located is a light-transmissive hole projection LSa, the second body portion projection 621a extends along the second direction X2, the straight line where the second body portion projection 621a is located overlaps the light-transmissive hole projection LSa, the second winding portion projection 622a overlaps the light-transmissive hole projection LSa along the first direction X1, and projections of second winding portions 622a of two of the second signal lines 620 are located on two opposite sides of the light-transmissive hole projection LSa along the first direction X1.

Specifically, referring to FIG. 36 and FIG. 37, the display panel 10 includes multiple first signal lines 610. The first signal line 610 includes a first body portion 611 and a first winding portion 612. The orthographic projection of the first body portion 611 on the substrate 100 and the orthographic projection of the first winding portion 612 on the substrate 100 do not overlap the orthographic projection of the light-transmissive hole LS on the substrate 100. The first body portion 611 extends along the first direction X1. The first winding portion 612 is configured to connect two adjacent first body portions 611. By avoiding the light-transmissive hole LS by the first winding portion 612, the first signal line 610 and the light-transmissive hole LS do not overlap along the thickness direction of the display panel 10.

Specifically, with reference to FIG. 37, the orthographic projection of the first body portion 611 on the plane where the substrate 100 is located is a first body portion projection 611a, the orthographic projection of the first winding portion 612 on the plane where the substrate 100 is located is a first winding portion projection 612a, and the orthographic projection of the light-transmissive hole LS on the plane where the substrate 100 is located is a light-transmissive hole projection LSa. The first body portion projection 611a extends along the first direction X1. Since the first body portion projection 611a overlaps the light-transmissive hole projection LSa along the first direction X1, if the first signal line 610 does not include the first winding portion 612, the first body portion 611 would block the light-transmissive hole LS. For the first winding portion 612, the first winding portion projection 612a overlaps the light-transmissive hole projection LSa along the second direction X2, that is, the first winding portion 612 makes the first signal line 610 avoid the light-transmissive hole LS, thereby ensuring that the projection of the first signal line 610 on the substrate 100 does not overlap the projection of the light-transmissive hole LS on the substrate 100 and ensuring the light transmittance of the display panel 10.

Further, referring to FIG. 36 and FIG. 38, the display panel 10 includes multiple second signal lines 620. The first second line 620 includes a second body portion 621 and a second winding portion 622. The orthographic projection of the second body portion 621 on the substrate 100 and the orthographic projection of the second winding portion 622 on the substrate 100 do not overlap the orthographic projection of the light-transmissive hole LS on the substrate 100. The second body portion 621 extends along the second direction X2. The second winding portion 622 is configured to connect two adjacent second body portions 621. By avoiding the light-transmissive hole LS by the second winding portion 622, the second signal line 620 and the light-transmissive hole LS do not overlap along the thickness direction of the display panel 10.

Specifically, with reference to FIG. 38, the orthographic projection of the second body portion 621 on the plane where the substrate 100 is located is a second body portion projection 621a, the orthographic projection of the second winding portion 622 on the plane where the substrate 100 is located is a second winding portion projection 622a, and the orthographic projection of the light-transmissive hole LS on the plane where the substrate 100 is located is a light-transmissive hole projection LSa. The second body portion projection 621a extends along the second direction X2. Since the second body portion projection 621a overlaps the light-transmissive hole projection LSa along the second direction X2, if the second signal line 620 does not include the second winding portion 622, the second body portion 621 would block the light-transmissive hole LS. For the second winding portion 622, the second winding portion projection 622a overlaps the light-transmissive hole projection LSa along the first direction X1, that is, the second winding portion 622 makes the second signal line 620 avoid the light-transmissive hole LS, thereby ensuring that the projection of the second signal line 620 on the substrate 100 does not overlap the projection of the light-transmissive hole LS on the substrate 100 and ensuring the light transmittance of the display panel 10.

With continued reference to FIG. 24, each repetitive light-emitting element group also includes a third light-emitting element column 3003 and a fourth light-emitting element column 3004. Along the first direction X1, the third light-emitting element column 3003 is located on the side of the first light-emitting element column 3001 facing away from the second light-emitting element column 3002, and the fourth light-emitting element column 3004 is located between the first light-emitting element column 3001 and the second light-emitting element column 3002. The third light-emitting element column 3003 and the fourth light-emitting element column 3004 each include a first-color light-emitting element 300A and a second-color light-emitting element 300B alternately arranged along the second direction X2. The emitted color of the first-color light-emitting element 300A and the emitted color of the second-color light-emitting element 300B are different from the emitted color of the third-color light-emitting element 300C.

Specifically, referring to FIG. 24, each repetitive light-emitting element group includes a first light-emitting element column 3001, a second light-emitting element column 3002, a third light-emitting element column 3003, and a fourth light-emitting element column 3004. Along the first direction X1, each repetitive light-emitting element group includes the following columns in sequence: a third light-emitting element column 3003, a first light-emitting element column 3001, a fourth light-emitting element column 3004, and a second light-emitting element column 3002.

Further, the first light-emitting element column 3001 and the second light-emitting element column 3002 each include third-color light-emitting elements 300C arranged along the second direction X2, and the third light-emitting element column 3003 and the fourth light-emitting element column 3004 each include a first-color light-emitting element 300A and a second-color light-emitting element 300B arranged in sequence along the second direction X2. The emitted color of the first-color light-emitting element 300A, the emitted color of the second-color light-emitting element 300B, and the emitted color of the third-color light-emitting element 300C are different so that light-emitting elements 300 of different colors can use pixel rendering or pixel borrowing to ensure the pixel resolution of the display panel in terms of the visual effect, thereby improving the display effect of the display panel 10.

Optionally, the first-color light-emitting element 300A includes a red light-emitting element, the second-color light-emitting element 300B includes a green light-emitting element, and the third-color light-emitting element 300C includes a blue light-emitting element. The red light-emitting element, the green light-emitting element, and the blue light-emitting element are driven to emit light, thereby achieving the color display effect of the display panel 10.

With continued reference to FIG. 2 to FIG. 24, the pixel circuit 200 includes a first-type transistor. The first-type transistor includes an active layer IGZO, a first gate BG located on the side of the active layer IGZO facing the substrate 100, and a second gate MG located on the side of the active layer IGZO facing away from the substrate 100. The display panel 10 also includes a signal line 600. The signal line 600 includes a scan signal line. The scan signal line is electrically connected to the first gate BG and the second gate MG of the same first-type transistor and is disposed in a different layer from the first gate BG and the second gate MG.

Specifically, referring to FIG. 2 to FIG. 5, the transistor in the pixel circuit 200 includes an active layer IGZO, a first gate BG, and a second gate MG. The active layer IGZO is located in the semiconductor layer 103. The first gate BG is located in the second metal layer 102. The second gate MG is located in the third metal layer 104. In this manner, the first gate BG may be understood as the bottom gate of the transistor, and the second gate MG may be understood as the top gate of the transistor. Thus, the transistor is a dual-gate transistor with top and bottom gates.

Further, as shown in FIG. 4 to FIG. 24, the scan signal lines electrically connected to the first gate BG and the second gate MG in the display panel 10 are disposed in different layers from the first gate BG and the second gate MG. By way of example, referring to FIG. 9, FIG. 12, and FIG. 13 or referring to FIG. 18, FIG. 21, and FIG. 22, the scan signal lines (for example, the first scan signal line G1, the second scan signal line G2, the third scan signal line G3, the first light emission control signal line EM1, and the second light emission control signal line EM2) are all disposed in the fourth metal layer 105. The scan signal lines located in the fourth metal layer 105 are electrically connected to the first gate BG and the second gate MG (disposed in different layers from the scan signal lines) through via holes. This ensures that the scan signal lines are disposed more flexibly.

Further, the pixel circuit 200 includes a first-type transistor. As shown in FIG. 2 to FIG. 24, the first-type transistor may be understood as a low-temperature polysilicon transistor. Optionally, the pixel circuit 200 may include an oxide transistor, or the pixel circuit 200 may include both a low-temperature polysilicon transistor and an oxide transistor.

With continued reference to FIG. 2 to FIG. 24, the scan signal lines include a first scan signal line G1, a second scan signal line G2, a third scan signal line G3, a first light emission control signal line EM1, and a second light emission control signal line EM2; the first-type transistors include a data write transistor T1, a threshold compensation transistor T2, a reset transistor T6, a first light emission control transistor T4, and a second light emission control transistor T5. The first scan signal line G1 is connected to the first gate BM and the second gate GM of the data write transistor T1. The second scan signal line G2 is connected to the first gate BM and the second gate GM of the threshold compensation transistor T2. The third scan signal line G3 is connected to the first gate BM and the second gate GM of the reset transistor T6. The first light emission control signal line EM1 is connected to the first gate BM and the second gate GM of the first light emission control transistor T4. The second light emission control signal line EM2 is connected to the first gate BM and the second gate GM of the second light emission control transistor T5.

Further, referring to FIG. 2, the scan signal lines electrically connected to the transistors in the display panel 10 may include a first scan signal line G1, a second scan signal line G2, a third scan signal line G3, a first light emission control signal line EM1, and a second light emission control signal line EM2. As shown in FIG. 13 and FIG. 22, the first scan signal line G1, the second scan signal line G2, the third scan signal line G3, the first light emission control signal line EM1, and the second light emission control signal line EM2 are all disposed in the film layer where the fourth metal layer 105 is located.

The first scan signal line G1 is electrically connected to the data write transistor T1. Specifically, the first scan signal line G1 is connected to the first gate BG and the second gate MG of the data write transistor T1. Referring to FIG. 9 and FIG. 13 or referring to FIG. 18 and FIG. 22, the first scan signal line G1 is connected to the first gate BG through a via hole. Referring to FIG. 12 and FIG. 13 or referring to FIG. 21 and FIG. 22, the first scan signal line G1 is connected to the second gate MG through a via hole.

The second scan signal line G2 is electrically connected to the threshold compensation transistor T2. Specifically, the second scan signal line G2 is connected to the first gate BG and the second gate MG of the threshold compensation transistor T2. Referring to FIG. 9 and FIG. 13 or referring to FIG. 18 and FIG. 22, the second scan signal line G2 is connected to the first gate BG through a via hole. Referring to FIG. 12 and FIG. 13 or referring to FIG. 21 and FIG. 22, the second scan signal line G2 is connected to the second gate MG through a via hole.

The third scan signal line G3 is electrically connected to the reset transistor T6. Specifically, the third scan signal line G3 is connected to the first gate BG and the second gate MG of the reset transistor T6. Referring to FIG. 9 and FIG. 13 or referring to FIG. 18 and FIG. 22, the third scan signal line G3 is connected to the first gate BG through a via hole. Referring to FIG. 12 and FIG. 13 or referring to FIG. 21 and FIG. 22, the third scan signal line G3 is connected to the second gate MG through a via hole.

The first light emission control signal line EM1 is electrically connected to the first light emission control transistor T4. Specifically, the first light emission control signal line EM1 is connected to the first gate BG and the second gate MG of the first light emission control transistor T4. Referring to FIG. 9 and FIG. 13 or referring to FIG. 18 and FIG. 22, the first light emission control signal line EM1 is connected to the first gate BG through a via hole. Referring to FIG. 12 and FIG. 13 or referring to FIG. 21 and FIG. 22, the first light emission control signal line EM1 is connected to the second gate MG through a via hole.

The second light emission control signal line EM2 is electrically connected to the second light emission control transistor T5. Specifically, the second light emission control signal line EM2 is connected to the first gate BG and the second gate MG of the second light emission control transistor T5. Referring to FIG. 9 and FIG. 13 or referring to FIG. 18 and FIG. 22, the second light emission control signal line EM2 is connected to the first gate BG through a via hole. Referring to FIG. 12 and FIG. 13 or referring to FIG. 21 and FIG. 22, the second light emission control signal line EM2 is connected to the second gate MG through a via hole.

With continued reference to FIG. 1 to FIG. 5 to FIG. 24, the pixel circuit 200 includes a reset transistor T6; the display panel also includes signal lines 600, and the signal lines 600 include reset signal lines VREF; the reset transistor T6 is electrically connected between the reset signal line VREF and the anode 310; the light-emitting elements 300 include first-color light-emitting elements 300A, second-color light-emitting elements 300B, and third-color light-emitting elements 300C that emit light of different colors; and the reset signal lines VREF include a first reset signal line VREFa, a second reset signal line VREFb, and a third reset signal line VREFc. The first reset signal line VREFa is electrically connected to the reset transistor T6 connected to the first-color light-emitting element 300A. The second reset signal line VREFb is electrically connected to the reset transistor T6 connected to the second-color light-emitting element 300B. The third reset signal line VREFc is electrically connected to the reset transistor T6 connected to the third-color light-emitting element 300C.

Further, referring to FIG. 2, the signal lines 600 include a reset signal line VREF, and the reset signal line VREF is electrically connected to the reset transistor T6 in the pixel circuit 200. When the reset transistor T6 is turned on, the reset signal in the reset signal line VREF can be transmitted to the pixel circuit 200. The reset transistor T6 is electrically connected between the reset signal line VREF and the anode 310. The reset signal transmitted through the reset transistor T6 can be transmitted to the anode 310 of the light-emitting element 300 to initialize the anode 310.

The display panel 10 includes multiple light-emitting elements 300 of different colors. Specifically, the light-emitting elements 300 include first-color light-emitting elements 300A, second-color light-emitting elements 300B, and third-color light-emitting elements 300C, thereby achieving the color display effect of the display panel 10.

Further, the reset signal lines VREF may include a first reset signal line VREFa, a second reset signal line VREFb, and a third reset signal line VREFc. The first reset signal line VREFa is electrically connected to the reset transistor T6 connected to the first-color light-emitting element 300A. The reset signal transmitted in the first reset signal line VREFa can initialize the anode 310 of the first-color light-emitting element 300A. The second reset signal line VREFb is electrically connected to the reset transistor T6 connected to the second-color light-emitting element 300B. The reset signal transmitted in the second reset signal line VREFb can initialize the anode 310 of the second-color light-emitting element 300B. The third reset signal line VREFc is electrically connected to the reset transistor T6 connected to the third-color light-emitting element 300C. The reset signal transmitted in the third reset signal line VREFc can initialize the anode 310 of the third-color light-emitting element 300C. The reset signal lines VREF ensure that the anodes 310 of light-emitting elements 300 of different colors can receive different reset signals and can accurately reset according to the light emission condition of the light-emitting elements 300, thereby ensuring the overall display effect of the display panel 10.

With continued reference to FIG. 5 to FIG. 24, the first reset signal line VREFa, the second reset signal line VREFb, and the third reset signal line VREFc are disposed in the same layer; or at least two of the first reset signal line VREFa, the second reset signal line VREFb, and the third reset signal line VREFc are disposed in different layers.

Further, the film layer positions of the first reset signal line VREFa, the second reset signal line VREFb, and the third reset signal line VREFc are flexible. It is feasible to dispose the first reset signal line VREFa, the second reset signal line VREFb, and the third reset signal line VREFc in the same layer, thereby reducing the number of film layers of the display panel 10 and facilitating the thin design of the display panel 10. It is also feasible to dispose at least two of the first reset signal line VREFa, the second reset signal line VREFb, and the third reset signal line VREFc in different layers, thereby increasing the distance between the lines transmitting different reset signals, reducing the interference generated between different reset signal lines VREF, ensuring the stability and reliability of signal transmission in the display panel 10, and ensuring the overall display effect of the display panel 10. The arrangement of different reset signal lines VREF in different film layers improves the flexibility of wiring in the film layers, reducing the difficulty of wiring in the film layers, and reducing the manufacturing costs of the display panel 10.

By way of example, referring to FIG. 6 to FIG. 15 or referring to FIG. 16 to FIG. 24, the first reset signal line VREFa and the second reset signal line VREFb are disposed in the film layer where the second metal layer 102 is located, and the third reset signal line VREFc is disposed in the film layer where the first metal layer 101 is located. Optionally, the film layer positions of the reset signal lines may also be adaptively adjusted as required. No more examples are given here.

With continued reference to FIG. 1 to FIG. 24, the pixel circuit 200 includes a first-type transistor and a storage capacitor Cst. The first-type transistor includes an active layer POLY, a first gate BG, and a second gate MG. The first gate BG is located on the side of the active layer IGZO facing the substrate 100. The second gate MG is located on the side of the active layer IGZO facing away from the substrate 100. The storage capacitor Cst includes a first capacitor plate C1 and a second capacitor plate C2 that are stacked. At least one of the first capacitor plate C1 or the second capacitor plate C2 is disposed in the same layer as at least one of the first gate BG or the second gate MG.

Further, the pixel circuit 200 also includes a storage capacitor Cst. The storage capacitor Cst can ensure that the potential of the first node N1 in the pixel circuit 200 is stable. The storage capacitor Cst includes a first capacitor plate C1 and a second capacitor plate C2. The first capacitor plate C1 and the second capacitor plate C2 are opposite along the thickness direction of the display panel 10.

Further, the capacitor plate in the storage capacitor Cst may be disposed in the same layer as the gate of the transistor, thereby reducing the number of film layers of the display panel 10 and facilitating the thin design of the display panel 10. Specifically, at least one of the first capacitor plate C1 or the second capacitor plate C2 is disposed in the same layer as at least one of the first gate BG or the second gate MG. By way of example, referring to FIG. 9 or FIG. 18, the first capacitor plate C1 is disposed in the first metal layer 101, and the second capacitor plate C2 and the first gate BG are disposed in the same layer. Optionally, in the display panel 10, it is also feasible to dispose the first capacitor plate C1 in the first metal layer 101 and dispose the second capacitor plate C2 and the second gate MG in the same layer. Optionally, it is also feasible to dispose the first capacitor plate C1 and the first gate BG in the same layer and dispose the second capacitor plate C2 and the second gate MG in different layers.

With continued reference to FIG. 1 to FIG. 24, the pixel circuit 200 includes a first light emission control transistor T4 and a drive transistor T3; the display panel 10 also includes signal lines 600, and the signal lines 600 include a first power signal line PVDD; the first light emission control transistor T4 is electrically connected between the first power signal line PVDD and the drive transistor T3; the first power signal line PVDD includes a first power signal line subportion PVDDa and a second power signal line subportion PVDDb, the first power signal line subportion PVDDa extends along the first direction X1, multiple first power signal line subportions PVDD are arranged along the second direction X2, the second power signal line subportion PVDDb extends along the second direction X2, and multiple second power signal line subportions PVDDb are arranged along the first direction X1; the second direction X2 intersects the first direction X1; and the first power signal line subportion PVDDa and the second power signal line subportion PVDDb are disposed in different layers.

Further, referring to FIG. 2, the signal lines 600 of the display panel 10 also include a first power signal line PVDD, and the first power signal line PVDD is electrically connected to the first light emission control transistor T4 in the pixel circuit 200. When the first light emission control transistor T4 is turned on, the power signal transmitted by the first power signal line PVDD is transmitted to the drive transistor T3 through the first light emission control transistor T4.

Further, referring to FIG. 13 and FIG. 14 or referring to FIG. 22 and FIG. 23, the first power signal line PVDD includes a first power signal line subportion PVDDa and a second power signal line subportion PVDDb. The first power signal line subportion PVDDa is located in the film layer where the fourth metal layer 105 is located. The second power signal line subportion PVDDb is located in the film layer where the fifth metal layer 106 is located. The first power signal line subportion PVDDa extends along the first direction X1. Multiple first power signal line subportions PVDD are arranged along the second direction X2. The second power signal line subportion PVDDb extends along the second direction X2. Multiple second power signal line subportions PVDDb are arranged along the first direction X1. The first power signal line PVDD is disposed in two film layers, and the extension wires of the first power signal line PVDD disposed in different layers intersect, that is, the first power signal line PVDD is a grid wire disposed in different layers, thereby reducing the resistance in the first power signal line PVDD, improving the stability and reliability of signal transmission in the first power signal line PVDD, and ensuring the display effect of the display panel 10.

With continued reference to FIG. 1 to FIG. 24, the display panel 10 also includes a first metal layer 101, a second metal layer 102, a semiconductor layer 103, a third metal layer 104, a fourth metal layer 105, and a fifth metal layer 106 that are stacked on one side of the substrate 100; the pixel circuit 200 includes a first-type transistor and a storage capacitor Cst, the first-type transistor includes an active layer POLY, a first gate BG, and a second gate MG, the first gate BG is located on the side of the active layer POLY facing the substrate 100, and the second gate MG is located on the side of the active layer POLY facing away from the substrate 100; the storage capacitor Cst includes a first capacitor plate C1 and a second capacitor substrate C2 that are stacked; the display panel 10 also includes signal lines 600, and the signal lines include scan signal lines, reset signal lines VREF, data signal lines DATA, and first power signal lines PVDD; and the reset signal lines VREF include a first reset signal line VREFa, a second reset signal line VREFb, and a third reset signal line VREFc, and the first power signal line PVDD includes a first power signal line subportion PVDDa and a second power signal line subportion PVDDb. The first capacitor plate C1 and the third reset signal line VREFc are located in the first metal layer 101. The first gate BG, the second reset signal line VREFb, and the first reset signal line VREFa are located in the second metal layer 102. The active layer POLY is disposed in the semiconductor layer 103. The second gate MG is located in the third metal layer 104. The scan signal line and the first power signal line subportion PVDDa are located in the fourth metal layer M4. The second power signal line subportion PVDDb, the data signal line DATA, and the anode connection portion 400 are located in the fifth metal layer.

Referring to FIG. 2 to FIG. 5, the transistor in the pixel circuit 200 includes an active layer IGZO, a first gate BG, and a second gate MG. The active layer IGZO is located in the semiconductor layer 103. The first gate BG is located in the second metal layer 102. The second gate MG is located in the third metal layer 104. In this manner, the first gate BG may be understood as the bottom gate of the transistor, and the second gate MG may be understood as the top gate of the transistor. Thus, the transistor is a dual-gate transistor with top and bottom gates.

Further, referring to FIG. 2, the scan signal lines electrically connected to the transistors in the display panel 10 may include a first scan signal line G1, a second scan signal line G2, a third scan signal line G3, a first light emission control signal line EM1, and a second light emission control signal line EM2. As shown in FIG. 13 and FIG. 22, the first scan signal line G1, the second scan signal line G2, the third scan signal line G3, the first light emission control signal line EM1, and the second light emission control signal line EM2 are all disposed in the film layer where the fourth metal layer 105 is located.

Further, the reset signal lines VREF may include a first reset signal line VREFa, a second reset signal line VREFb, and a third reset signal line VREFc. The first reset signal line VREFa is electrically connected to the reset transistor T6 connected to the first-color light-emitting element 300A. The reset signal transmitted in the first reset signal line VREFa can initialize the anode 310 of the first-color light-emitting element 300A. The second reset signal line VREFb is electrically connected to the reset transistor T6 connected to the second-color light-emitting element 300B. The reset signal transmitted in the second reset signal line VREFb can initialize the anode 310 of the second-color light-emitting element 300B. The third reset signal line VREFc is electrically connected to the reset transistor T6 connected to the third-color light-emitting element 300C. The reset signal transmitted in the third reset signal line VREFc can initialize the anode 310 of the third-color light-emitting element 300C. The reset signal lines VREF ensure that the anodes 310 of light-emitting elements 300 of different colors can receive different reset signals and can accurately reset according to the light emission condition of the light-emitting elements 300, thereby ensuring the overall display effect of the display panel 10.

Further, the pixel circuit 200 also includes a storage capacitor Cst. The storage capacitor Cst can ensure that the potential of the first node N1 in the pixel circuit 200 is stable. The storage capacitor Cst includes a first capacitor plate C1 and a second capacitor plate C2. The first capacitor plate C1 and the second capacitor plate C2 are opposite along the thickness direction of the display panel 10.

Further, referring to FIG. 2, the signal lines 600 of the display panel 10 also include a first power signal line PVDD, and the first power signal line PVDD is electrically connected to the first light emission control transistor T4 in the pixel circuit 200. When the first light emission control transistor T4 is turned on, the power signal transmitted by the first power signal line PVDD is transmitted to the drive transistor T3 through the first light emission control transistor T4.

Referring to FIG. 9 or FIG. 18, the first capacitor plate C1 and the third reset signal line VREFc are located in the first metal layer 101. Referring to FIG. 10 or FIG. 19, the first gate BG, the second reset signal line VREFb, and the first reset signal line VREFa are located in the second metal layer 102. Referring to FIG. 11 or FIG. 20, the active layer POLY is disposed in the semiconductor layer 103. Referring to FIG. 13 or FIG. 22, the second gate MG is located in the third metal layer 104, and the scan signal line and the first power signal line subportion PVDDa are located in the fourth metal layer M4. Referring to FIG. 14 or FIG. 23, the second power signal line subportion PVDDb, the data signal line DATA, and the anode connection portion 400 are located in the fifth metal layer. The arrangement of part of the structures in the same layer improves the utilization rate of the space where the film layers in the display panel 10 are located, reduces the overall film layer thickness of the display panel 10, and facilitates the thin design of the display panel 10.

Based on the same inventive concept, embodiments of the present invention also provide a display device. FIG. 39 is a diagram illustrating the structure of a display device according to embodiments of the present invention. As shown in FIG. 39, the display device 1 includes the display module 10 of any previous embodiment and thus has the corresponding beneficial effects in the preceding embodiments. The details are not described here. The display device 1 may be an electronic device such as a mobile phone, a computer, a smart wearable device (for example, a smartwatch), or an in-vehicle display device.

It is to be noted that the preceding are preferred embodiments of the present invention and technical principles used therein. It is to be understood by those skilled in the art that the present invention is not limited to the embodiments described herein. For those skilled in the art, various apparent modifications, adaptations, and substitutions can be made without departing from the scope of the present invention. Therefore, though the present invention is described in detail through the preceding embodiments, the present invention is not limited to the preceding embodiments and may include other equivalent embodiments without departing from the concept of the present invention. The scope of the present invention is determined by the scope of the appended claims.

What is claimed is:

1. A display panel, comprising:
a substrate;
a plurality of pixel circuits and a plurality of light-emitting elements located on one side of the substrate, wherein a light-emitting element comprises an anode; and
a plurality of anode connection portions, wherein at least part of the plurality of anode connection portions each comprise a connection subportion and a compensation subportion, wherein
the connection subportion connects a pixel circuit and the anode, and the plurality of anode connection portions and anodes of the plurality of light-emitting elements are disposed in different layers; and
the compensation subportion is located on a side of the anode facing the substrate, and along a thickness direction of the display panel, at least part of the compensation subportion does not overlap the connection subportion.

2. The display panel of claim 1, wherein
the connection subportion comprises a pixel circuit connection terminal, and the pixel circuit connection terminal connects the connection subportion and the pixel circuit; and
among the plurality of anode connection portions, two pixel circuit connection terminals of two anode connection portions arranged along a first direction are arranged along the first direction, and the first direction is parallel to a plane where the substrate is located.

3. The display panel of claim 1, wherein
the connection subportion comprises an anode connection terminal, and the anode connection terminal connects the connection subportion and the anode; and
among the plurality of anode connection portions, two anode connection terminals of two anode connection portions arranged along a first direction are staggered along the first direction, and the first direction is parallel to a plane where the substrate is located.

4. The display panel of claim 3, wherein
the connection subportion further comprises a pixel circuit connection terminal, and the pixel circuit connection terminal connects the connection subportion and the pixel circuit; and
among the plurality of anode connection portions, the anode connection terminals of the two anode connection portions arranged along the first direction are located on different sides of pixel circuit connection terminals of the two anode connection portions.

5. The display panel of claim 1, wherein
the connection subportion comprises a pixel circuit connection terminal and an anode connection terminal, the pixel circuit connection terminal connects the connection subportion and the pixel circuit, and the anode connection terminal connects the connection subportion and the anode;
the plurality of light-emitting elements comprise a first-color light-emitting element, a second-color light-emitting element, and a third-color light-emitting element, and an emitted color of the first-color light-emitting element, an emitted color of the second-color light-emitting element, and an emitted color of the third-color light-emitting element are different;
among the plurality of anode connection portions, in an anode connection portion connected to the first-color light-emitting element, the pixel connection terminal is located on a side of the anode connection terminal facing away from the compensation subportion; and
among the plurality of anode connection portions, in an anode connection portion connected to the second-color light-emitting element or the third-color light-emitting element, the pixel connection terminal is located on a side of the anode connection terminal facing the compensation subportion.

6. The display panel of claim 1, wherein
the connection subportion comprises a pixel circuit connection terminal and an anode connection terminal, the pixel circuit connection terminal connects the connection subportion and the pixel circuit, and the anode connection terminal connects the connection subportion and the anode;
the plurality of light-emitting elements comprise a first-color light-emitting element, a second-color light-emitting element, and a third-color light-emitting element, and an emitted color of the first-color light-emitting element, an emitted color of the second-color light-emitting element, and an emitted color of the third-color light-emitting element are different;
among the plurality of anode connection portions, two anode connection portions connected to first-color light-emitting elements and adjacent to each other along a second direction comprise a first anode connection portion and a second anode connection portion, the pixel circuit connection terminal in the first anode connection portion is located on a side facing the anode connection terminal in the second anode connection portion, and the second direction is parallel to a plane where the substrate is located;
among the plurality of anode connection portions, two anode connection portions connected to second-color light-emitting elements and adjacent to each other along the second direction comprise a third anode connection portion and a fourth anode connection portion, and the anode connection terminal in the third anode connection portion is located on a side facing the pixel circuit connection terminal in the fourth anode connection portion; and
among the plurality of anode connection portions, two anode connection portions connected to third-color light-emitting elements and adjacent to each other along the second direction comprise a fifth anode connection portion and a sixth anode connection portion, and the pixel circuit connection terminal in the fifth anode connection portion is located on a side facing the pixel circuit connection terminal in the sixth anode connection portion, or the anode connection terminal in the fifth anode connection portion is located on a side facing the anode connection terminal in the sixth anode connection portion.

7. The display panel of claim 1, wherein the connection subportion and the compensation subportion are disposed in a same layer.

8. The display panel of claim 1, wherein the connection subportion and the compensation subportion are disposed in different layers.

9. The display panel of claim 1, wherein along the thickness direction of the display panel, the connection subportion partially overlaps the compensation subportion.

10. The display panel of claim 1, wherein the plurality of anode connection portions comprise a seventh anode connection portion and an eighth anode connection portion arranged along a second direction, an extension length L1 of the seventh anode connection portion along the second direction and an extension length L2 of the eighth anode connection portion along the second direction satisfy |L1−L2|/L1 ≤20%, and the second direction is parallel to a plane where the substrate is located.

11. The display panel of claim 10, wherein the seventh anode connection portion and the eighth anode connection portion are any two anode connection portions arranged along the second direction.

12. The display panel of claim 10, wherein the seventh anode connection portion and the eighth anode connection portion have a same shape.

13. The display panel of claim 1, wherein the plurality of anode connection portions comprise a ninth anode connection portion and a tenth anode connection portion that are arranged along a first direction and are connected to light-emitting elements of a same color, and the first direction is parallel to a plane where the substrate is located; and
an extension length L3 of the ninth anode connection portion along a second direction and an extension length L4 of the tenth anode connection portion along the second direction satisfy |L1−L4|/L3 ≤20%, and the second direction is parallel to the plane where the substrate is located and intersects the first direction.

14. The display panel of claim 13, wherein the ninth anode connection portion and the tenth anode connection portion have a same shape.

15. The display panel of claim 1, wherein
the plurality of light-emitting elements comprise a first-color light-emitting element, a second-color light-emitting element, and a third-color light-emitting element, and an emitted color of the first-color light-emitting element, an emitted color of the second-color light-emitting element, and an emitted color of the third-color light-emitting element are different; and
among the plurality of anode connection portions, an extension length, along a second direction, of an anode connection portion connected to the first-color light-emitting element or the second-color light-emitting element is less than or equal to an extension length, along the second direction, of an anode connection portion connected to the third-color light-emitting element.

16. The display panel of claim 1, wherein
the display panel comprises a plurality of repetitive light-emitting element groups disposed in an array;
each of the plurality of repetitive light-emitting element groups comprises a first light-emitting element column and a second light-emitting element column arranged along a second direction, each of the first light-emitting element column and the second light-emitting element column comprises two third-color light-emitting elements arranged along the second direction, a first spacing is provided between the two third-color light-emitting elements in the first light-emitting element column, a second spacing is provided between the two third-color light-emitting elements in the second light-emitting element column, the first spacing is less than the second spacing, and the second direction intersects a first direction; and
the display panel further comprises an auxiliary structure, and the auxiliary structure overlaps the second spacing along the thickness direction of the display panel.

17. The display panel of claim 16, wherein
two anode connection portions connected to the two third-color light-emitting elements in the first light-emitting element column comprise an eleventh anode connection portion and a twelfth anode connection portion;
two anode connection portions connected to the two third-color light-emitting elements in the second light-emitting element column comprise a thirteenth anode connection portion and a fourteenth anode connection portion;
in the eleventh anode connection portion, the compensation subportion is located on a side of the connection subportion facing the twelfth anode connection portion;
in the twelfth anode connection portion, the compensation subportion is located on a side of the connection subportion facing the eleventh anode connection portion;
in the thirteenth anode connection portion, the compensation subportion is located on a side of the connection subportion facing away from the fourteenth anode connection portion; and
in the fourteenth anode connection portion, the compensation subportion is located on a side of the connection subportion facing away from the thirteenth anode connection portion.

18. The display panel of claim 17, wherein
the connection subportion comprises an anode connection terminal, and the anode connection terminal connects the connection subportion and the anode;
the compensation subportion comprises a virtual anode connection terminal;
the virtual anode connection terminal in the eleventh anode connection portion is disposed in correspondence with the anode connection terminal in the twelfth anode connection portion;
the virtual anode connection terminal in the twelfth anode connection portion is disposed in correspondence with the anode connection terminal in the eleventh anode connection portion;
the virtual anode connection terminal in the thirteenth anode connection portion is disposed in correspondence with the anode connection terminal in the fourteenth anode connection portion; and
the virtual anode connection terminal in the fourteenth anode connection portion is disposed in correspondence with the anode connection terminal in the thirteenth anode connection portion.

19. The display panel of claim 16, wherein along the thickness direction of the display panel, the anode of the third-color light-emitting element at least partially overlaps an anode connection portion electrically connected to the third-color light-emitting element.

20. A display device, comprising a display panel, wherein the display panel comprises:
a substrate;
a plurality of pixel circuits and a plurality of light-emitting elements located on one side of the substrate, wherein a light-emitting element comprises an anode; and
a plurality of anode connection portions, wherein at least part of the plurality of anode connection portions each comprise a connection subportion and a compensation subportion, wherein
the connection subportion connects a pixel circuit and the anode, and the plurality of anode connection portions and anodes of the plurality of light-emitting elements are disposed in different layers; and
the compensation subportion is located on a side of the anode facing the substrate, and along a thickness direction of the display panel, at least part of the compensation subportion does not overlap the connection subportion.
